(19) United States
(12) Patent Application Publication
(10) Pub. No.: US 2026/0154476 A1
(43) Pub. Date: Jun. 4, 2026

(54) Optimization Using Machine Learning Proxies and Rejection Sampling

(71) Applicant: Chevron U.S.A. Inc., San Ramon, CA (US)

(72) Inventors: Zhenzhen WANG, Houston, TX (US); Shusei TANAKA, Houston, TX (US); Yanfen ZHANG, Mandeville, LA (US); Xian-Huan WEN, Humble, TX (US)

(73) Assignee: Chevron U.S.A. Inc., San Ramon, CA (US)

(21) Appl. No.: 18/964,443

(22) Filed: Dec. 1, 2024

(51) Int. Cl. G06F 30/27

(52) U.S. Cl. CPC G06F 30/27

(57) ABSTRACT

A method is described for building a numerical model. The method includes (a) defining a plurality of objective functions; (b) defining a plurality of parameters and obtaining a plurality of values for the plurality of parameters; (c) determining a plurality of simulation candidates from a plurality of iterations; and (d) filtering the plurality of simulation candidates from the plurality of iterations to select at least one numerical model for generating a prediction. For each iteration, the method includes: creating a plurality of proxies for each objective function and selecting a created proxy for each objective function, where at least one created proxy for each objective function includes a machine learning proxy, performing Monte Carlo sampling using the selected proxies and the defined plurality of parameters, and rejecting a subset of the created plurality of Monte Carlo samples responsive to the plurality of objective functions and acceptance criteria.

### CROSS-REFERENCE TO RELATED APPLICATIONS

Not applicable.

### STATEMENT REGARDING FEDERALLY SPONSORED RESEARCH OR DEVELOPMENT

Not applicable.

### TECHNICAL FIELD

The disclosed embodiments relate generally to techniques of building a numerical model.

### BACKGROUND

Numerical modeling is computationally expensive. However, accurate quantification of uncertainties, such as in history matching for production forecasting in the oil and gas industry, is crucial to our ability to make the most appropriate choices for purchasing materials, operating safely, and successfully completing projects. Decisions include, but are not limited to, budgetary planning, obtaining mineral and lease rights, signing well commitments, permitting rig locations, designing well paths and drilling strategies, preventing subsurface integrity issues by planning proper casing and cementation strategies, selecting and purchasing appropriate completion and production equipment, injection strategies, reservoir management, etc. Thus, there exists a need for an improved manner to build a numerical model.

### SUMMARY

In accordance with some embodiments, a method of building a numerical model is disclosed. In one embodiment, the method includes (a) defining a plurality of objective functions; (b) defining a plurality of parameters and obtaining a plurality of values for the plurality of parameters; (c) determining a plurality of simulation candidates from a plurality of iterations; and (d) filtering the plurality of simulation candidates from the plurality of iterations to select at least one numerical model for generating a prediction. For each iteration, the method includes (i) running a simulation using the obtained plurality of parameters and the obtained plurality of values for the plurality of parameters to generate a plurality of simulation samples for the plurality of objective functions. Each simulation sample includes the corresponding parameter values, and each simulation sample corresponds to at least one objective function with corresponding objective function values. For each iteration, the method includes (ii) creating a plurality of proxies for each objective function and selecting a created proxy for each objective function. At least one created proxy for each objective function includes a machine learning proxy. For each iteration, the method includes (iii) performing Monte Carlo sampling using the selected proxies and the defined plurality of parameters to create a plurality of Monte Carlo samples. Each MC sample includes parameter values and objective function values. For each iteration, the method includes (iv) rejecting a subset of the created plurality of Monte Carlo samples responsive to the plurality of objective functions and acceptance criteria. The rejection sampling results in a plurality of accepted Monte Carlo samples. For each iteration, the method includes (v) selecting a plurality of simulation candidates from the plurality of accepted Monte Carlo samples for the next iteration.

In another aspect of the present invention, to address the aforementioned problems, some embodiments provide a non-transitory readable storage medium storing one or more programs. The one or more programs comprise instructions, which when executed by a computer system with one or more processors and memory, cause the computer system to perform any of the methods provided herein.

In yet another aspect of the present invention, to address the aforementioned problems, some embodiments provide a computer system. The computer system includes one or more processors, memory, and one or more programs. The one or more programs are stored in memory and configured to be executed by the one or more processors. The one or more programs include an operating system and instructions that when executed by the one or more processors cause the computer system to perform any of the methods provided herein.

### BRIEF DESCRIPTION OF THE DRAWINGS

FIG. 1A illustrates an example system of building a numerical model. FIG. 1B illustrates an example method of building a numerical model. FIG. 1C illustrates a non-limiting example of a two-parameter one-objective HM problem.

FIGS. 2A and 2B illustrate rejection sampling in ML Proxies-Assisted IRSO.

FIG. 3 illustrates simulation candidate selection in ML Proxies-Assisted IRSO.

FIG. 4 illustrates natural selection, crossover, and mutation in GA.

FIGS. 5A-5C illustrate an overview of three analytical functions. FIG. 5A illustrates a Himmelblau function. FIG. 5B illustrates a Booth function. FIG. 5C illustrates a Lévi function.

FIGS. 6A-6F illustrate a comparison of objective function vs. the number of simulations among ML Proxies-Assisted IRSO, GA, and PSO for the minimization of a six-parameter three-objective analytic case.

FIGS. 7A-7I illustrates a comparison of sampling results among ML Proxies-Assisted IRSO, GA, and PSO for the minimization of a six-parameter three-objective analytic case.

FIG. 8A illustrates a histogram of good and top cases of ML Proxies-Assisted IRSO, GA, and PSO. FIGS. 8B-8D illustrate proxy quality of three ML Proxies-Assisted IRSO scenarios.

FIGS. 9A-9F illustrates a comparison of objective function vs. the number of simulations among three ML Proxies-Assisted IRSO scenarios for the minimization of a six-parameter three-objective analytic case.

FIGS. 10A-10I illustrates a comparison of sampling results among three ML Proxies-Assisted IRSO scenarios for the minimization of a six-parameter three-objective analytic case.

FIG. 11 illustrates an overview of the 30 regions in the Brugge model.

FIGS. 12A-12F illustrate a comparison of objective functions vs. number of simulations among ML Proxies-Assisted IRSO, GA, and PSO for the 120-parameter five-objective Brugge field case.

FIGS. 13A-13C illustrate of ML Proxies-Assisted IRSO, GA, and PSO sampling with the first six parameters for the 120-parameter five-objective Brugge field case (dots represent top/good/all cases).

FIG. 14A illustrates a histogram of good and top cases of ML Proxies-Assisted IRSO, GA, and PSO. FIG. 14B illustrates proxy quality of ML Proxies-Assisted IRSO for the 120-parameter five-objective Brugge field case.

FIGS. 15A-15J illustrate a comparison of the first iteration/generation (gray curves), top cases (darker curves in FIGS. 15A, 15C, 15E, 15G, and 15I as well as the darker curves with arrows in FIGS. 15B, 15D, 15F, 15H, and 15J), good cases of GA (darker curves without arrows in FIGS. 15B, 15D, 15F, 15H, and 15J) and observation data (black boxes) between ML Proxies-Assisted IRSO and GA for the 120-parameter five-objective Brugge field case, illustrated with the second well of each objective function.

FIGS. 16A-16D illustrate a comparison of objective functions vs. the number of simulations between ML Proxies-Assisted IRSO and GA for the field application.

FIGS. 17A-17B illustrate ML Proxies-Assisted IRSO and GA sampling with six parameters for the field application (dots represent top/good/all cases).

FIG. 18A illustrates a histogram of good and top cases of ML Proxies-Assisted IRSO and GA. FIG. 18B illustrates proxy quality of ML Proxies-Assisted IRSO for the field application.

FIGS. 19A-19D illustrate a comparison of top cases between ML Proxies-Assisted IRSO and GA for the field application.

FIGS. 20A-20C illustrate nomenclature utilized in this disclosure.

Like reference numerals refer to corresponding parts throughout the drawings.

### DETAILED DESCRIPTION OF EMBODIMENTS

The process of history matching (HM) for an asset involves adjusting the parameters of the reservoir model to align with the observation data. The objective of this inverse modeling procedure is to improve the precision and reliability of future production forecasts by reducing uncertainties in the model parameters. Recent years have witnessed the development of various HM methods, broadly categorized as probabilistic and deterministic approaches, and the probabilistic methods can be further divided into Bayesian and non-Bayesian heuristic optimization techniques. The HM quality is critical in ensuring the accuracy and reliability of subsurface models and production forecasts. Thus, achieving a high-quality match relies on selecting the appropriate HM method.

Deterministic methods employ the gradient information of model parameters to quantify how the model updates affect the corresponding responses. These methods, exemplified by gradient descent, aim to minimize the discrepancy between observation data and simulation responses by optimizing model changes. They can be combined with techniques such as probability perturbation or dimension reduction to incorporate prior geological information. Through the HM process, deterministic methods can calibrate representative models within the uncertainty range for local parameter adjustment.

Bayesian probabilistic methods in HM involve sampling from prior uncertainty parameters first and then minimizing the HM error by maximizing the posterior probability. This is achieved by combining the prior probability with the likelihood, estimated by the difference between model responses and data measurements, via Bayes' theorem. In many practical scenarios, the prior probability is typically represented with several reservoir models, and the posterior probability is optimized by updating solutions statistically. Markov Chain Monte Carlo (MCMC) is one such method, incorporating acceptance-rejection sampling techniques such as the Metropolis-Hastings or Hamiltonian algorithm to accurately capture the posterior distributions using numerous simulation runs. To reduce the computational cost, proxy-space sampling via Design of Experiments (DoE) is often used during the sampling process.

Ensemble methods, also falling under the Bayesian probabilistic category, include techniques such as the ensemble Kalman filter and ensemble smoother with multiple data assimilation. Assuming Gaussian distributions between both the model input parameters and measurement errors and a linear relationship between the model and predicted data, these methods aim to determine the maximum likelihood estimates of the input model parameters by minimizing the variance of posterior error. In field applications, a sequential or iterative scheme is often used to address problem nonlinearity, and localization or bootstrap resampling may be used to counteract the effects of spurious correlation resulting from limited sample sizes. The use of gradient information in the parameter update gives ensemble methods an advantage over rejection-sampling methods, particularly when problems have many uncertainty parameters and multiple measured points.

Non-Bayesian probabilistic algorithms, also called heuristic methods, rely on heuristic processes to find combinations of input parameters to optimize the objective function. In an HM scenario, the model parameters are updated in a randomized manner to reduce the misfit between historical data and simulation results. Two typical examples of this category include GA and PSO. Despite not being designed for uncertainty assessment or probabilistic HM, these non-Bayesian approaches are popular for both deterministic and probabilistic HM workflows due to their robustness and ability to handle complex field problems. To compare GA and PSO with Bayesian approaches, one has to filter the entire population history to approximate the posterior distribution. Technical papers showcase diverse applications of heuristic algorithms, including identifying representative models through cluster analysis and optimizing drilling sequences.

Multiobjective HM is often used to obtain multiple geological models by exploring the solution space from Pareto fronts. To address multiple objectives, the most popular approach is to combine the objectives into an aggregated scalar function, which is the weighted sum of all the HM objectives. This approach is widely used due to its simplicity; however, the weights are usually unknown beforehand, and thus unbalanced HM outcomes are often achieved. Therefore, one may need to trial and error several times to find the appropriate weights for objective functions that have different units, ranges, and measurement errors for each specific field application. Another approach is to use optimizers that are able to handle various objectives, such as multiobjective GA, multiobjective PSO, and Nondominated Sorting Genetic Algorithm II. These optimizers are good at balancing the conflicts among objectives, so there is no need to do so artificially. The drawback is that the multiobjective process is usually computationally prohibitive because it always needs to go through an iterative procedure that requires hundreds or even thousands of simulation runs.

Recently, many researchers have used various proxies that correlate the input parameters to the output objectives to facilitate the multiobjective optimization process. For example, one approach took advantage of artificial neural network (ANN) and PSO to optimize oil recovery, CO2 storage, and net present value for CO2 enhanced oil recovery projects; another approach coupled ANN with Nondominated Sorting Genetic Algorithm II to boost both the oil recovery factor and net present value. These studies unveiled the extraordinary benefits and great potential of proxies in speeding up the optimization procedure. The effectiveness of these approaches and their limitations often depend on the specific problem, especially when applied to fields. It is essential to understand the strengths and weaknesses of each method before choosing a single or combined approach(es) for HM.

To summarize, first, history matching methods include deterministic methods that use gradient information to minimize discrepancies between observed data and simulation responses. Although deterministic methods may be efficient for local parameter adjustments and incorporating prior geological information, unfortunately, deterministic methods may get trapped in local optima and are less effective for problems with many uncertainty parameters. Second, history matching methods include probabilistic methods that include Bayesian and non-Bayesian approaches, such as Markov Chain Monte Carlo (MCMC) and ensemble methods like the ensemble Kalman filter. Although probabilistic methods may provide a robust framework for uncertainty quantification and can handle complex, nonlinear problems, unfortunately, probabilistic methods may be computationally expensive due to the need for numerous simulation runs. Third, history matching methods include heuristic methods such as non-Bayesian algorithms like genetic algorithms (GA) and particle swarm optimization (PSO) that rely on heuristic processes to optimize model parameters. Although heuristic methods may be robust and capable of handling complex field problems, unfortunately, heuristic methods often require trial and error to find appropriate weights for multi-objective functions and can be computationally prohibitive.

Described below are methods, systems, and computer readable storage media that provide a manner of building a numerical model is disclosed. In one embodiment, the method includes (a) defining a plurality of objective functions; (b) defining a plurality of parameters and obtaining a plurality of values for the plurality of parameters; (c) determining a plurality of simulation candidates from a plurality of iterations; and (d) filtering the plurality of simulation candidates from the plurality of iterations to select at least one numerical model for generating a prediction. For each iteration, the method includes (i) running a simulation using the obtained plurality of parameters and the obtained plurality of values for the plurality of parameters to generate a plurality of simulation samples for the plurality of objective functions. Each simulation sample includes the corresponding parameter values, and each simulation sample corresponds to at least one objective function with corresponding objective function values. For each iteration, the method includes (ii) creating a plurality of proxies for each objective function and selecting a created proxy for each objective function. At least one created proxy for each objective function includes a machine learning proxy. For each iteration, the method includes (iii) performing Monte Carlo sampling using the selected proxies and the defined plurality of parameters to create a plurality of Monte Carlo samples. Each MC sample includes parameter values and objective function values. For each iteration, the method includes (iv) rejecting a subset of the created plurality of Monte Carlo samples responsive to the plurality of objective functions and acceptance criteria. The rejection sampling results in a plurality of accepted Monte Carlo samples. For each iteration, the method includes (v) selecting a plurality of simulation candidates from the plurality of accepted Monte Carlo samples for the next iteration.

These embodiments are designed to be of particular use for generating a prediction. The prediction may be utilized for reservoir modeling, physical tasks, etc., in the oil and gas industry. Besides reservoir modeling, the prediction may be utilized for fluid injection into a wellbore (e.g., waterflooding, hydraulic fracturing, etc.), infill wellbore drilling, other wellbore operations, and other aspects in the oil and gas industry. The prediction may be utilized in the context of a conventional formation (e.g., with a vertical wellbore). The prediction may be utilized in the context of an unconventional formation (e.g., with a horizontal wellbore).

The resulting numerical model(s) from embodiments consistent with this disclosure may be utilized for a variety of purposes. For example, the resulting numerical model(s) may be utilized in reservoir management, including enhancing the accuracy of reservoir models to improve decision-making in field development and production optimization. As another example, the resulting numerical model(s) may be utilized for uncertainty quantification, including providing a robust framework for quantifying uncertainties in subsurface models, leading to more reliable production forecasts. As another example, the resulting numerical model(s) may be utilized for field development planning, including supporting the design and evaluation of various field development scenarios by accurately predicting production outcomes under different conditions. As another example, by integrating ML proxies with iterative rejection sampling, more efficient and accurate history matching may be performed, ultimately leading to better reservoir management and optimized production strategies.

Advantageously, embodiments consistent with this disclosure may lead to improvements in efficiency, accuracy, diversity, or any combination thereof as compared to existing solutions. Regarding efficiency, embodiments consistent with this disclosure may reduce the number of simulation runs needed, making it more computationally efficient. By using ML proxies, the number of required simulation runs may be reduced, significantly lowering computational costs. Regarding accuracy, embodiments consistent with this disclosure may, by iteratively improving proxies and using rejection sampling, ensure a better match to observation data. For instance, iterative rejection sampling may ensure that the selected simulation models closely match the observed data, improving the reliability of the outcomes (e.g., HM outcomes). Regarding diversity, embodiments consistent with this disclosure may maintain a high diversity of model parameters, which is crucial for reliable production forecasting. For instance, a high diversity of model parameters may be maintained, which is crucial for capturing subsurface uncertainties and making reliable production forecasts.

Advantageously, embodiments consistent with this disclosure may improve outcomes for all objective functions simultaneously (e.g., improve HM outcomes for all objective functions simultaneously). For instance, a difference compared to previous approaches is multi-objective optimization, as embodiments consistent with this disclosure may simultaneously optimize multiple objective functions, balancing the trade-offs between different targets (e.g., HM targets). Advantageously, embodiments consistent with this disclosure may reduce computational costs by using machine learning (ML) proxies to efficiently explore the solution space. For instance, a difference compared to previous approaches is the integration of ML proxies. Unlike traditional approaches that rely solely on deterministic or probabilistic approaches, embodiments consistent with this disclosure may use ML proxies to predict the outcomes of simulation runs, reducing the need for extensive simulations. Advantageously, embodiments consistent with this disclosure may preserve subsurface uncertainty by selecting new simulation designs from accepted Monte Carlo samples. For instance, a difference compared to previous approaches is rejection sampling, as embodiments consistent with this disclosure may iteratively refine the selection of simulation candidates, ensuring that only the most accurate numerical model(s) are retained.

Indeed, the effectiveness of subsurface assessment for various field development scenarios relies on accurately quantifying uncertainties during production forecasts. This disclosure discusses a design-of-experiment (DoE)-based multiobjective history matching (HM) workflow using Machine Learning (ML) Proxies-Assisted Iterative Rejection Sampling Optimization (IRSO). The HM target is to improve the HM outcome of all the objectives simultaneously and attain a series of reliable simulation models for production forecasting after a predefined number of iterations. The instant workflow takes full advantage of various proxies to efficiently explore the solution space via Monte Carlo (MC) sampling. The MC samples are iteratively rejected according to each objective function, and the new simulation designs for the next iteration are intentionally selected from the accepted MC samples to best preserve the subsurface uncertainty.

It is worth noting that embodiments consistent with this disclosure are not limited to history matching even though history matching is discussed herein for simplicity. Embodiments consistent with this disclosure may be utilized for history matching problems as well as non-history matching problems such as optimization problems (e.g., minimization problems). For example, low error and high error discussion for a history matching problem herein may be replaced with low value and high value, respectively, for an optimization problem (e.g., minimization problem). Thus, the terminology ML Proxies-Assisted Iterative Rejection Sampling Optimization (IRSO) is utilized herein to convey that this disclosure is not limited to history matching.

Reference will now be made in detail to various embodiments, examples of which are illustrated in the accompanying drawings. In the following detailed description, numerous specific details are set forth in order to provide a thorough understanding of the present disclosure and the embodiments described herein. However, embodiments described herein may be practiced without these specific details. In other instances, well-known methods, procedures, components, and mechanical apparatus have not been described in detail so as not to unnecessarily obscure aspects of the embodiments.

The methods and systems of the present disclosure may, in part, use one or more models that are machine-learning algorithms. These models may be supervised or unsupervised. Supervised learning algorithms are trained using labeled data (i.e., training data) which consist of input and output pairs. By way of example and not limitation, supervised learning algorithms may include classification and/or regression algorithms such as neural networks, generative adversarial networks, linear regression, etc. Unsupervised learning algorithms are trained using unlabeled data, meaning that training data pairs are not needed. By way of example and not limitation, unsupervised learning algorithms may include clustering and/or association algorithms such as k-means clustering, principal component analysis, singular value decomposition, etc. Although the present disclosure may name specific models, those of skill in the art will appreciate that any model that may accomplish the goal may be used. As described herein, at least one created proxy for each objective function includes a machine learning proxy using an artificial neural network, random forest, etc.

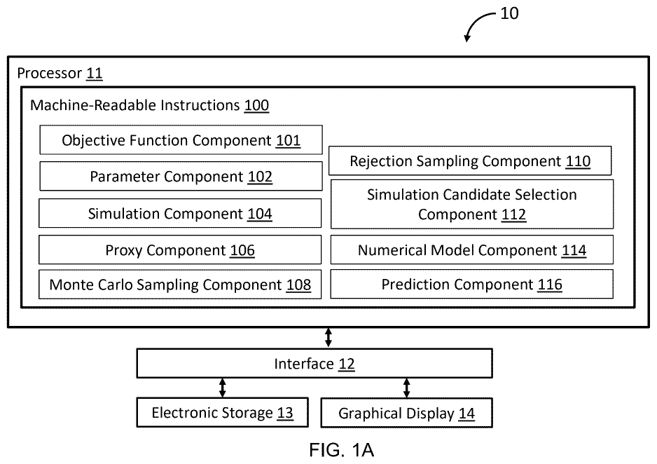

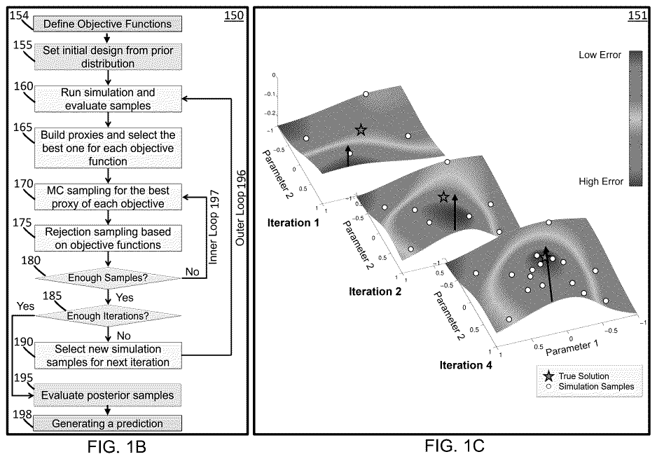

The methods and systems of the present disclosure may be implemented by a system and/or in a system, such as a system 10 shown in FIG. 1A. The system 10 may include one or more of a processor 11, an interface 12 (e.g., bus, wireless interface), an electronic storage 13, a graphical display 14, and/or other components. The processor 11 may execute a method of building a numerical model using machine learning proxies and rejection sampling in an iterative manner. The method includes input such as a plurality of objective functions, a plurality of parameters, a plurality of values for the plurality of parameters, quantity of iterations, acceptance criteria, quantity of simulation candidates, threshold(s), quantity of numerical models to select, etc. The method includes output such as simulation candidates from the plurality of iterations, selected numerical model(s), generated prediction(s), etc.

The electronic storage 13 may be configured to include any electronic storage medium that electronically stores information. The electronic storage 13 may store software algorithms, information determined by the processor 11, information received remotely, and/or other information that enables the system 10 to function properly. For example, the electronic storage 13 may store information relating to input such as the plurality of objective functions, the plurality of parameters, the plurality of values for the plurality of parameters, the quantity of iterations, the acceptance criteria, the quantity of simulation candidates, the threshold(s), the quantity of numerical models, and/or other information. For example, the electronic storage 13 may store information relating to output such as the simulation candidates from the plurality of iterations, the selected numerical model(s), the generated prediction(s), and/or other information. The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may include one or more non-transitory computer readable storage mediums storing one or more programs. The electronic storage 13 may be a separate component within the system 10, or the electronic storage 13 may be provided integrally with one or more other components of the system 10 (e.g., the processor 11). Although the electronic storage 13 is shown in FIG. 1A as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

The graphical display 14 may refer to an electronic device that provides a visual presentation of information. The graphical display 14 may include a color display and/or a non-color display. The graphical display 14 may be configured to visually present information. The graphical display 14 may present information using/within one or more graphical user interfaces. For example, the graphical display 14 may present information relating to the simulation candidates from the plurality of iterations, the selected numerical model(s), the generated prediction(s), and/or other information.

The processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 100 to facilitate building a numerical model. The machine-readable instructions 100 may include one or more computer program components. The machine-readable instructions 100 may include a objective function component 101, a parameter component 102, a simulation component 104, a proxy component 106, a Monte Carlo sampling component 108, a rejection sampling component 110, a simulation candidate selection component 112, a numerical model component 114, a prediction component 116, and/or other computer program components. As will be described further in the context of FIG. 1B, some aspects will be performed in an iterative manner.

It should be appreciated that although computer program components are illustrated in FIG. 1A as being co-located within a single processing unit, one or more of the computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 100, this is merely for case of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

Referring again to machine-readable instructions 100, the objective function component 101 may be configured to define a plurality of objective functions.

The parameter component 102 may be configured to define a plurality of parameters and obtain a plurality of values for the plurality of parameters.

The simulation component 104 may be configured to run a simulation using the obtained plurality of parameters and the obtained plurality of values for the plurality of parameters to generate a plurality of simulation samples for a plurality of objective functions. Each simulation sample includes the corresponding parameter values. Each simulation sample corresponds to at least one objective function with corresponding objective function values. The simulation component 104 may include usage of a simulator (e.g., reservoir simulator or other simulator utilized in the oil and gas industry). One or more other components may also include usage of the simulator.

The proxy component 106 may be configured to create a plurality of proxies for each objective function and select a created proxy for each objective function. At least one created proxy for each objective function includes a machine learning proxy.

The Monte Carlo sampling component 108 may be configured to perform Monte Carlo sampling using the selected proxies and the defined plurality of parameters to create a plurality of Monte Carlo samples. Each MC sample includes parameter values and objective function values.

The rejection sampling component 110 may be configured to reject a subset of the created plurality of Monte Carlo samples responsive to the plurality of objective functions and acceptance criteria. The rejection sampling results in a plurality of accepted Monte Carlo samples.

The simulation candidate selection component 112 may be configured to select a plurality of simulation candidates from the plurality of accepted Monte Carlo samples for the next iteration.

The numerical model component 114 may be configured to filter the plurality of simulation candidates from the plurality of iterations to select at least one numerical model for generating a prediction.

The prediction component 116 may be configured to generate the prediction utilizing the at least one numerical model that was selected.

The description of the functionality provided by the different computer program components described herein is for illustrative purposes, and is not intended to be limiting, as any of the computer program components may provide more or less functionality than is described. For example, one or more of the computer program components may be eliminated, and some or all of its functionality may be provided by other computer program components. As another example, processor 11 may be configured to execute one or more additional computer program components that may perform some or all of the functionality attributed to one or more of the computer program components described herein.

Machine learning has revolutionized various fields by enabling computers to learn from data and make informed decisions. Traditional algorithms, while effective, often rely on fixed rules and predefined routines. In contrast, the proposed system harnesses the power of machine learning architectures that transcend these limitations.

A system for building a numerical model using machine learning proxies may include the following components:
1. Deep Learning Models:
   In some embodiments, system 10 may use deep learning models. These models consist of multiple layers of interconnected neurons, mimicking the human brain's neural structure.
   Notable deep learning architectures include:
      Convolutional Neural Networks (CNNs): often used for image processing, CNNs excel at feature extraction and pattern recognition.
      Recurrent Neural Networks (RNNs): often used for sequential data, RNNs maintain internal states to process sequences effectively.
      Long Short-Term Memory (LSTM)/Gated Recurrent Unit (GRU): these are variants of RNNs that address long-range dependencies.
      Autoencoders (AE): often used for dimensionality reduction and feature learning.
      Restricted Boltzmann Machine (RBM): this is a generative stochastic neural network.
      Deep Belief Networks (DBN): DBNs are hierarchical structures for feature learning and classification.
2. Dynamic Functioning:
   Unlike preprogrammed algorithms, the machine learning architectures within System 10 operate dynamically. Their behavior adapts based on real-time factors such as input data, processing time, and random seeds.
   This dynamic functioning allows the system to handle complex tasks beyond human capabilities.
3. Applications:
   System 10 applies these architectures to analyze data sets, uncover hidden patterns, and solve intricate problems.
   By surpassing predefined routines, the system achieves results that extend well beyond abstract ideas and mental processes.

The adaptive, dynamic nature and utilization of advanced architectures redefine the boundaries of computational capabilities. By design, machine learning architectures function outside of any preprogrammed routines. Thus, the training and/or analysis performed by machine learning architectures is not performed by predefined computer algorithms but rather improves the functioning of the computer system and extends well beyond mental processes and abstract ideas.

FIG. 1B illustrates a non-limiting example process 150 of building a numerical model. The process 150 uses ML proxies and rejection sampling. The process 150 is one non-limiting example of ML Proxies-Assisted Iterative Rejection Sampling Optimization (IRSO). The process 150 is illustrated in FIG. 1B and a non-limiting example 151 is illustrated in FIG. 1C for ease of understanding. In FIG. 1C, the white dots on the surface are the simulation samples with the objective function interpreted by the ML-based response surface. Note that in the example 151, the vertical axis of the objective function is in reverse order. The arrows in FIG. 1C point to the colored regions representing the favorable range of the objective function where HM error is low. Due to the limited number of simulation samples, the objective function covered by the ML proxy may not be accurate. To verify the accuracy of the ML proxy, the simulation sampling continues iteratively while cross-validating the accuracy of the proxy prediction to the simulation results. As the iteration increases, the proxy surface keeps improving as the simulation sample (white dots) selected near the true solution (star symbols) increases. The process 150 is validated first through a simple scenario made of a series of analytical functions (i.e., the HM Analytic Case) and then via a designed complex HM problem for the Brugge field (i.e., Brugge Case) with the pros and cons of each approach demonstrated. Subsequently, the process 150 was applied to an actual offshore asset (i.e., Field Case) to demonstrate its advantages over the reference. Its advantages over the commonly available optimizers such as GA and PSO are also discussed herein.

At step 154, the process 150 includes defining a plurality of objective functions. The objective functions are specified by users, and they are the items that users are interested in. Users may determine the type of optimization problem (e.g., minimization or maximization). If it is a HM problem (minimization), users may determine how many objective functions they want to set up. The same type of property may be grouped into the same objective functions, as they share the same unit and a similar magnitude. Alternatively, the same type of property may be split into multiple objective functions for a more balanced HM outcome.

The definition of objective functions may be determined before running any workflows including ML Proxies-Assisted IRSO, and therefore, it may be done before the step 155. When setting up the objective functions, users may specify which properties to extract from numerical model predictions as well as provide the corresponding measurement values and the measurement error values estimated by their best knowledge, which are used for calculating the HM errors—objective function values. For objective functions, the objective function values may be directly calculated from simulation samples.

The plurality of objective functions may include objective functions for single objective optimization. In one embodiment, the plurality of objective functions may include a Himmelblau function. In one embodiment, the plurality of objective functions may include a Booth function. In one embodiment, the plurality of objective functions may include a Levi function. In one embodiment, the plurality of objective functions may include a Rastrigin function. In one embodiment, the plurality of objective functions may include an Ackley function. In one embodiment, the plurality of objective functions may include a Sphere function. In one embodiment, the plurality of objective functions may include a Rosenbrock function. In one embodiment, the plurality of objective functions may include a Beale function. In one embodiment, the plurality of objective functions may include a Goldstein-Price function. This is not an exhaustive list of objective functions. Single objective functions may also be combined in some embodiments. For instance, the Himmelblau function, Booth function, and Levi function were combined together to make a problem multi-objective as described further hereinbelow.

The plurality of objective functions may include objective functions for multi-objective optimization. In one embodiment, the plurality of objective functions may include a Binh and Korn function. In one embodiment, the plurality of objective functions may include a Chankong and Haimes function. In one embodiment, the plurality of objective functions may include a Fonseca-Fleming function. In one embodiment, the plurality of objective functions may include a Osyczka and Kundu function. This is not an exhaustive list of objective functions.

The plurality of objective functions include various types of user-specified metrics and/or properties. For HM problems, these refer to HM error that can be calculated using numerical sample predictions, data measurements, and confidence interval of each data measurement (i.e., measurement error). For other optimization problems, these properties refer to those that users are most interested in to maximize or minimize, e.g., NPV, DPI, cost, etc.

At step 155, the process 150 includes defining a plurality of parameters and obtaining a plurality of values for the plurality of parameters. The plurality of parameters may include parameters corresponding to static properties of a subsurface formation. In one embodiment, the plurality of parameters may include a permeability (k) parameter. In one embodiment, the plurality of parameters may include a porosity (ø) parameter. In one embodiment, the plurality of parameters may include a viscosity (u) parameter. In one embodiment, the plurality of parameters may include a pore volume multiplier parameter. In one embodiment, the plurality of parameters may include a permeability multiplier parameter. In one embodiment, the plurality of parameters may include a vertical to horizontal permeability ratio parameter. In one embodiment, the plurality of parameters may include a skin factor parameter. In one embodiment, the plurality of parameters may include a permeability parameter, a porosity parameter, a viscosity parameter, a pore volume multiplier parameter, a permeability multiplier parameter, a vertical to horizontal permeability ratio parameter, a skin factor parameter, or any combination thereof. This is not an exhaustive list. These parameters and the plurality of values for the parameters may be utilized for the iterations as discussed hereinbelow.

At least two parameters may be utilized in the step 155. The upper limit on the quantity of parameters may depend on the desired prediction, a balance between resource usage and speed, etc. In some embodiments, the upper limit on the quantity of parameters is 50. Thus, 2 to 50 parameters may be defined in some embodiments. The plurality of values for the plurality of parameters may include distributions with minimum and maximum values (e.g., a range of −1 to 1 values), continuously obtained values, discrete values, etc.

As illustrated in the example 151 of FIG. 1C, parameter 1 and parameter 2 may be defined. Values from −1 to 1 may be obtained for parameter 1 as illustrated in FIG. 1C. Values from −1 to 1 may be obtained for parameter 2 as illustrated in FIG. 1C.

Next, a plurality of simulation candidates may be determined from a plurality of iterations. Turning to an outer loop 196 in FIG. 1B, each iteration may proceed through the outer loop 196, which includes steps 160, 165, 170, 175, 180, 185, and 190. An inner loop 197 in FIG. 1B may be utilized for the steps 170, 175, and 180. The quantity of iterations may be provided by a user as user input. In one embodiment, the quantity of iterations may be 5-50 iterations (e.g., about 20 iterations).

For each iteration, at the step 160, the process 150 includes running a simulation using the obtained plurality of parameters and the obtained plurality of values for the plurality of parameters to generate a plurality of simulation samples for the plurality of objective functions. Each simulation sample includes the corresponding parameter values. Each simulation sample corresponds to at least one objective function (e.g., corresponds to one or more objective functions) with corresponding objective function values. At least one simulation run may be performed in the step 160. The objective function values may include history matching errors, which may be illustrated on the z-axis (e.g., z-axis visible in iteration 1 in FIG. 1C). A particular history matching error may represent a mismatch between a numerical model prediction and observation data or data measurement (e.g., ground truth or true solution as illustrated with star symbols in FIG. 1C). The step 160 generally includes performing simulation runs following the design and post-process results to evaluate the objective functions. These simulation samples from the step 160 may be used to build proxies at step 165.

A sampling algorithm may be utilized to generate the plurality of simulation samples in the step 160. In one embodiment, the sampling algorithm may include a Latin hypercube sampling algorithm (e.g., by Beachkofski, B. and Grandhi, R. 2002. Improved Distributed Hypercube Sampling. Paper presented at the 43rd AIAA/ASME/ASCE/AHS/ASC Structures, Structural Dynamics, and Materials Conference, Denver, Colorado, USA, 22-25 April. https://doi.org/10.2514/6.2002-1274, which is incorporated by reference). In one embodiment, the sampling algorithm may include a one-variable-at-a-time (OVAT) algorithm. In one embodiment, the sampling algorithm may include a Plackett-Burman algorithm. In one embodiment, the sampling algorithm may include a Plackett-Burman with center point algorithm. In one embodiment, the sampling algorithm may include a Folded Plackett-Burman algorithm. In one embodiment, the sampling algorithm may include a Folded Plackett-Burman with center point algorithm. In one embodiment, the sampling algorithm may include a 2-level full factorial algorithm. In one embodiment, the sampling algorithm may include a 3-level full factorial algorithm. In one embodiment, the sampling algorithm may include an exhaustive set algorithm. In one embodiment, the sampling algorithm may include a D-Optimal (linear) algorithm. In one embodiment, the sampling algorithm may include a D-Optimal (linear interaction) algorithm. In one embodiment, the sampling algorithm may include a D-Optimal (full quadratic) algorithm. In one embodiment, the sampling algorithm may include a central composite algorithm. In one embodiment, the sampling algorithm may include a space-filling (Hammersley sequence) algorithm. In one embodiment, the sampling algorithm may include a space-filling (Sobol sequence) algorithm. In one embodiment, the sampling algorithm may include a random algorithm. This list of sampling algorithms is not exhaustive.

Each simulation sample corresponds to at least one objective function (e.g., corresponds to one or more objective functions) with corresponding objective function values. In one embodiment, the plurality of objective functions may include a Himmelblau function. In one embodiment, the plurality of objective functions may include a Booth function. In one embodiment, the plurality of objective functions may include a Levi function. This list of objective functions is not exhaustive.

As illustrated in the example 151 in FIG. 1C, for the first iteration, a sampling algorithm, such as the Latin hypercube sampling algorithm (e.g., by Beachkofski, B. and Grandhi, R. 2002. Improved Distributed Hypercube Sampling. Paper presented at the 43rd AIAA/ASME/ASCE/AHS/ASC Structures, Structural Dynamics, and Materials Conference, Denver, Colorado, USA, 22-25 April. https://doi.org/10.2514/6.2002-1274, which is incorporated by reference) may be utilized to represent the parameter space. Four simulation samples may be generated with the sampling algorithm using parameter 1 and parameter 2, with each parameter having a range of −1 to 1. These four simulation samples correspond to one objective function for simplicity; thus, FIG. 1C illustrates a two-parameter one-objective function HM problem. Portions with lower error are illustrated with arrows for convenience. These four simulation samples are illustrated as white dots in iteration 1 in FIG. 1C. Of note, four additional simulation samples may be added in each iteration in the example 151, and therefore, iteration 2 is illustrated with eight simulation samples in FIG. 1C, iteration 3 would have twelve simulation samples (not shown), and iteration 4 is illustrated with sixteen simulation samples in FIG. 1C, and so on.

For each iteration, at step 165, the process 150 includes creating a plurality of proxies for each objective function and selecting a created proxy for each objective function. At least one created proxy for each objective function includes a machine learning (ML) proxy. The step 165 may include building proxies for all the objective functions using both ordinary/non-ML proxies and ML proxies. In one embodiment, the plurality of proxies may include at least one analytical proxy, such as, but not limited to, linear, linear with cross terms, quadratic polynomial, full quadratic (e.g., quad. poly. with cross terms), etc. In one embodiment, the plurality of proxies may include at least one data-exact proxy, such as, but not limited to, Kriging, Splines, etc. In one embodiment, the plurality of proxies may include at least one machine learning proxy, such as, but not limited to, artificial neural network (ANN) (e.g., using C++ or Python), ridge regression, lasso regression, support vector regression (SVR), random forest, adaptive boosting (AdaBoost), gradient boosting, etc. In one embodiment, the plurality of proxies may include artificial neural network, ridge regression, lasso regression, support vector regression, random forest, adaptive boosting, gradient boosting, Kriging, Splines, linear, linear with cross terms, quadratic polynomial, full quadratic, or any combination thereof. This list of proxies is not exhaustive. The proxy quality of each created proxy may be evaluated, and the best-performing proxy for each objective function may be selected.

Indeed, various proxies may be utilized to capture the relationships between model parameters and outputs, for example, four ordinary proxies (e.g., Splines, Kriging, and quadratic polynomials with/without cross-terms) and seven ML proxies. The ML proxies may include one neural network, two advanced polynomial regression approaches, one support vector regressor, and three tree-based ensemble methods. The hyper-parameters of ML proxies may be fixed, and this section provides more information about the ML proxies.

Artificial Neural Network (ANN)—ANN is a multilayer perceptron that tries to replicate the behavior of brain neurons to achieve complex decisions. It is usually made of one input layer representing the features, several hidden layers to transform values from the previous layer with a combination of weighted linear summation and nonlinear mapping by an activation function, and one output layer that converts the outcome into output values. ANN parameters are tuned to minimize the loss function. In this disclosure, the values of hyper-parameters are chosen as follows: The number of hidden layers is three; the hyperbolic tangent function serves as the activation function; the maximum number of iterations is 5,000; L₂ regularization term weight α=0.0001 in the loss function; and the learning rate is fixed at 0.001 for the optimizer Adam used in the training process (e.g., Kingma, D. P. and Ba, J. 2014. Adam: A Method for Stochastic Optimization. arXiv:1412.6980 (preprint; last revised 30 Jan. 2017). https://doi.org/10.48550/arXiv.1412.6980, which is incorporated by reference).

Ridge Regression-Ridge regression aims to address some issues in the ordinary least squares (e.g., overfitting, instability, singular or near singular matrix). It shrinks the regression coefficients (β) by introducing a penalty term on the L₂ norm, and it targets to minimize a penalized residual sum of squares as follows:

$${min}_{β , {β}_{0}} \frac{1}{\text{?}} {‖ y - f ( x , β , {β}_{0} ) ‖}_{2}^{2} + α {‖ β ‖}_{2}^{2} , \qquad Equation ( 1 )$$

$$where$$

$$f ( x , β , {β}_{0} ) = {β}^{T} x + {β}_{0} , \qquad Equation ( 2 )$$

$$\text{?} \text{indicates text missing or illegible when filed}$$

β is the vector of coefficients and β₀ denotes the bias term. The prefactor of the L₂ norm, α (α≥0), controls the shrinkage level that increases along with a. The regression coefficients are shrunk toward zero and α=0.1 is used in this disclosure.

Lasso Regression—Like ridge, the least absolute shrinkage and selection operator (usually written as Lasso in the ML field) is also a shrinkage method with a constraint on the L₁ norm of the regression coefficients instead:

$${min}_{β , {β}_{0}} \frac{1}{2 \text{?}} {‖ y - f ( x , β , {β}_{0} ) ‖}_{2}^{2} + α {‖ β ‖}_{1} . \qquad Equation ( 3 )$$

$$\text{?} \text{indicates text missing or illegible when filed}$$

Compared with ridge, some of the coefficients could shrink exactly to zeros. Thus, Lasso could help reduce the number of variables by eliminating the least important features from the model. The prefactor of the L₁ norm, α, is also set to be 0.1 in this disclosure.

Support Vector Regression (SVR)—The goal of SVR is to minimize the sum of squared weights (β) subject to small error. Under given hyperparameters and C>0, the standard form of kernel-based SVR can be expressed as follows:

$$\begin{matrix}\text{?} & \frac{1}{2} {‖ β ‖}_{2}^{2} + {Ce}^{T} ( ξ + {ξ}^{*} ) \\ subject to & {y}_{i} - \hat{f} ( {x}_{i} , β , {β}_{0} ) ⩽ ε + {ξ}_{i} , \\ & \hat{f} ( {x}_{i} , β , {β}_{0} ) - {y}_{i} ⩽ ε + {ξ}_{i}^{*} , \\ & {ξ}_{i} + {ξ}_{i}^{*} ⩾ 0 , i = \text{?} , … , \text{?}\end{matrix} , \qquad Equation ( 4 )$$

$$where$$

$$\hat{f} ( {x}_{i} , β , {β}_{0} ) = {β}^{T} ϕ ( x ) + {β}_{0} , \qquad Equation ( 5 )$$

$$\text{?} \text{indicates text missing or illegible when filed}$$

φ(x) maps x into a higher dimensional space; ε defines a penalty-free margin between a prediction and the true value; ξ/ξ* are the error slacks for samples that lie above/below the ε margin; and C controls the influence of error. Usually, the corresponding dual problem is solved instead:

$$\begin{matrix}\text{?} & \frac{1}{2} {( a - {a}^{*} )}^{T} Q ( a - {a}^{*} ) + ε {e}^{T} ( a \text{?} {a}^{*} ) + {y}^{T} ( a - {a}^{*} ) \\ subject to & {e}^{T} ( a - {a}^{*} ) = 0 , \\ & 0 ⩽ {a}_{i} , \text{?} ⩽ C , i = 1 , … , \text{?}\end{matrix} , \qquad Equation ( 6 )$$

$$\text{?} \text{indicates text missing or illegible when filed}$$

where Qᵢⱼ=K(xᵢ,xⱼ)≡φ*xᵢ)^{T}φ(xⱼ) is the kernel and the approximate function is

$$\hat{f} ( x , {β}_{0} ) = \text{?} ( {a}_{i} - {a}_{i}^{*} ) K ( {x}_{i} , x ) + {β}_{0} \text{?} \qquad Equation ( 7 )$$

$$\text{?} \text{indicates text missing or illegible when filed}$$

SVR can handle high-dimensional spaces and is not overly sensitive to overfitting. It is well-suited for small to medium data sets, while the training time is prohibitive for large data sets. This disclosure chooses the radial basis function as the kernel function, ε=0.1, and C=1.

Random Forest—Random forest is one of the tree-based ensemble methods. It uses a series of decision trees that fit the data set and improve the prediction accuracy. Each tree only inspects a random subset of the features, and the average prediction of trees is returned during a regression process. Thus, it can limit the correlation with other trees in the forest and reduce overfitting issues in decision trees. In this disclosure, the number of trees is 100; the maximum depth of trees is one (i.e., a stump); the minimum number of samples to split an internal node is two; the minimum number of samples required to be at a leaf node is one; and all the features are considered when looking for the best split.

Adaptive Boosting (AdaBoost)—The second tree-based ensemble method is AdaBoost. As the name indicates, AdaBoost adaptively raises the weights of those misclassified instances by the previous decision trees. Thus, the subsequent trees can better focus on the challenging instances and improve accuracy. Even though each tree is simple and weak, AdaBoost can gradually improve the performance one after another, resulting in a strong learner. In this disclosure, the maximum depth of trees is four; the maximum number of trees at which boosting is terminated is set to be 300, and the weight applied to each regressor is one.

Gradient Boosting—Gradient boosting is the third tree-based ensemble method. Similar to AdaBoost, gradient boosting iteratively creates new decision trees, and each tree grows on top of the previous ones as it aims at reducing the error made by the previous trees. Unlike AdaBoost, the weights of the training samples are not tweaked; instead, each predictor is trained using the residual errors of the predecessor as labels. By fitting a small tree to the residuals, gradient boosting slowly improves prediction in areas where it does not perform well. Aggregation is done by adding the first tree predictions and a shrunk version of the following trees. In this disclosure, the maximum depth of trees is one, which is usually called a stump; the squared error of the regression is the loss function to be optimized; the learning rate that shrinks the contribution of each tree is 0.1; and the number of boosting stages is 100.

Proxy Creation and Test/Proxy Quality—At the step 165, the process 150 may build various proxies per objective function (e.g., 11 types of proxies mixed from numerical regressions and ML-based methods per HM objective function) using the simulation samples from the step 160. Among proxies (e.g., the 11 proxies), the one with the highest proxy quality may be used for each objective function (e.g., for each HM objective function) to attain the Monte Carlo (MC) sample responses for rejection sampling. The proxy quality R is defined as follows:

$$R = \frac{{σ}_{\hat{d} , \tilde{d}}}{{σ}_{\hat{d}} \cdot {σ}_{\tilde{d}}} , \qquad Equation ( 8 )$$

where \hat{d} is objective function estimated from simulation samples, \tilde{d} is proxy estimate with \hat{d} as blind data, σ_{\hat{d}} and σ_{\tilde{d}} are their corresponding standard deviations, and σ_{\hat{d},\tilde{d}} is covariance between them. This disclosure uses tenfold cross-validation that requires rebuilding the proxy ten times during each test to balance the accuracy and computational efficiency.

Returning to the process 150, for each iteration, Monte Carlo (MC) sampling and rejection sampling of MC samples may be performed via the inner loop 197 with steps 170, 175, and 180 in FIG. 1B. At the step 170 of the inner loop 197, the process 150 includes performing Monte Carlo (MC) sampling using the selected proxies (from the step 165) and the defined plurality of parameters (from the step 155) to create a plurality of Monte Carlo (MC) samples at the step 170. Each MC sample includes parameter values and objective function values. The step 170 generates Nₛ MC samples and attains the corresponding responses from each proxy model. In other words, the step 170 creates MC samples and predicts their responses using the selected proxies. For instance, thousands of MC samples (e.g., 10,000 MC samples) may be created in the step 170.

Monte Carlo (MC) sampling here refers to a process to (1) generate parameter values of each MC sample and (2) attain the corresponding objective function value from the corresponding proxy model. Latin hypercube sampling may be used to generate parameter values, and the reference is: Beachkofski, B. and Grandhi, R. 2002. Improved Distributed Hypercube Sampling. Paper presented at the 43rd AIAA/ASME/ASCE/AHS/ASC Structures, Structural Dynamics, and Materials Conference, Denver, Colorado, USA, 22-25 April. https://doi.org/10.2514/6.2002-1274, which is incorporated by reference.

At the step 175 of the inner loop 197, the process 150 includes rejecting a subset of the created plurality of Monte Carlo (MC) samples responsive to the plurality of objective functions and acceptance criteria resulting in a plurality of accepted Monte Carlo samples. The rejection sampling results in a plurality of accepted Monte Carlo samples. The step 175 performs rejection sampling to filter out MC samples that do not meet the acceptance criteria as well as collects accepted MC samples and uses them to guide the next iteration of simulations.

At the step 180 of the inner loop 197, the process 150 includes determining if enough accepted MC samples remain after the rejection sampling in the step 175. For the rejection sampling of the MC samples, the target may be to collect N, MC samples which is set as 0.5Nₛ. If the number of MC samples accepted Nₐ reaches the target Nₜ at the step 180, terminate the inner loop 197, and go to the next step 185. Otherwise, repeat the steps 170 and 175 with a new random seed. At least one subiteration is utilized for performing Monte Carlo sampling and rejecting a subset of the created plurality of Monte Carlo samples. Note that the maximum number of MC samples accepted per the inner loop 197 may be set as 0.1Nₛ, so the inner loop 197 needs to be repeated at least five times to collect enough samples (0.5Nₛ).

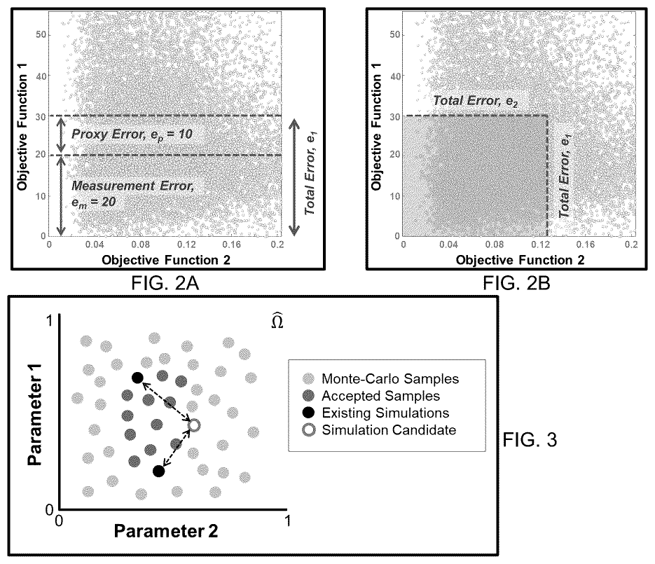

Rejection Sampling-Unlike traditional rejection sampling approaches that calculate acceptance probability to determine whether to accept or reject a sample, the step 175 uses direct cutoffs for each objective function (e.g., for each HM objective function). FIGS. 2A and 2B illustrate an example of two objective functions, where the gray dots represent MC samples in the solution space. Taking Objective Function 1 as an example, the total error e₁=eₘ+eₚ is used as the initial acceptance criteria during rejection sampling. e is mainly made up of two parts—measurement error eₘ and proxy error eₚ. Given N_{d} observation data, eₘ is simply the weighted root mean square of the individual measurement error of each observation:

$${e}_{m} = \sqrt{\frac{{\sum }_{i = 1}^{{N}_{d}} {w}_{i} {e}_{m , i}}{{\sum }_{i = 1}^{{N}_{d}} {w}_{i}}} , \qquad Equation ( 9 )$$

where e_{m,i} requires user estimate based on the reliability of data measurement. More specifically, eₘ is measurement error, w is weight of observation data, and N_{d} is number of observation data. This disclosure assumes the weights w of all the N_{d} observation data are equal. For the Nₕ simulation samples collected so far, eₚ is estimated as follows:

$${e}_{p} = \sqrt{\frac{1}{{N}_{h}} {\sum }_{i = 1}^{{N}_{h}} \vert {\hat{d}}_{i} - {\tilde{d}}_{i} \vert} . \qquad Equation ( 10 )$$

where eₚ is proxy error, \hat{d} is objective function estimated from simulation results, \tilde{d} is proxy estimate with \hat{d} as blind data. Nₕ is size of Sₕ, and Sₕ is a set of historical simulation runs.

Total error is e=eₘ+eₚ. The acceptance thresholds may be determined based on e's with possible adjustments according to the number of MC samples that passed the acceptance criteria. In one embodiment, each accepted MC sample satisfies the thresholds of all the objective functions.

The example shown in FIGS. 2A and 2B assumes eₘ=20 and eₚ=10, so e₁=30 is used as the acceptance-rejection criterion of Objective Function 1. Following the same procedure, the step 175 attains the initial acceptance-rejection criteria for all the objective functions. As the right subplot in FIG. 2B indicates, MC samples that fall in the shadow region satisfy all the acceptance criteria, and thus they should be added to Sₐ. Unlike multiobjective optimizations that select samples along the Pareto front, the step 175 performs a series of direct cutoffs to approximate the posterior distribution. This approach provides advantages for two reasons: (1) The goal of HM, for instance, is to balance and improve all the objective functions simultaneously, and the step 175 avoids MC samples that favor some objective functions over the rest, and (2) the difficulty of locating the Pareto front of MC samples grows as the number of objective functions increases, while this is not an issue for the acceptance-rejection strategy in the step 175. More information is available in Park, H.-Y., Datta-Gupta, A., and King, M. J. 2015. Handling Conflicting Multiple Objectives Using Pareto-Based Evolutionary Algorithm during History Matching of Reservoir Performance. J Pet Sci Eng 125:48-66. https://doi.org/10.1016/j.petrol.2014.11.006, which is incorporated by reference.

Users may provide eₘ when defining objective functions, and eₚ may be automatically calculated as part of the process 150. The total error e=eₘ+eₚ, and the acceptance criteria is determined based on e with possible adjustments according to the number of MC samples that passed the acceptance criteria.

Following the aforementioned strategy, the maximum number of MC samples accepted per inner loop is 0.1Nₛ. the step 175 records the number of accepted MC samples for each objective function separately, which will be used to adjust the acceptance-rejection criteria whenever necessary. In the most ideal situation, there are enough MC samples left at the first subiteration under a certain inner loop, indicating the initial acceptance-rejection criteria have worked well. The step 175 randomly selects 0.1Nₛ samples and adds them to Su. However, this is not always the case for many reasons (e.g., the proxy quality and reliability of some objective functions may be low to estimate eₚ, the MC sample distributions of some objective functions are skewed); therefore, it is worth mentioning the strategy that loosens the selection criteria to increase Nₐ and hence avoids performing many inner loops:
a) For an arbitrary objective function j, the inner loop 197 excludes it from the rejection sampling process when Rⱼ<0.1 to avoid narrowing the solution space with a poor quality proxy. Unreliable proxies are likely to appear during the first several iterations due to the limited simulation samples in Sₕ, especially for complex problems with a large number of uncertainty parameters (e.g., HM problems with a large number of uncertainty parameters). In general, the proxy quality improves as the number of iterations increases.
b) The number of posterior MC samples is orders of magnitude lower than 0.1Nₛ due to an underestimate of either eₘ or from the user input eₚ from an unreliable proxy. For an arbitrary objective function j under this circumstance, the inner loop 197 makes a relaxation to its cutoff tolerance and captures the posterior distribution with a wider confidence range: eⱼ+min(\overline{\tilde{d}}ⱼ/5,eⱼ)→eⱼ (at most 100% increase), where \overline{\tilde{d}}ⱼ is the average of \tilde{d}ⱼ.
c) In most scenarios, plenty of MC samples are left but the number is below 0.1Nₛ. The inner loop 197 identifies the bottleneck objective functions that accept MC samples either less than 0.1Nₛ or below the average number of MC accepted samples contributed solely by each objective function. For an arbitrary objective function j under this circumstance, the inner loop 197 makes a mild relaxation to its cutoff tolerance:

$${e}_{j} + max ( {σ}_{{\tilde{d}}_{j}} / 5 , {e}_{j} / 5 ) \to {e}_{j}$$

(at least 20% increase), where

$${σ}_{{\tilde{d}}_{j}}$$

is the standard deviation of \tilde{d}ⱼ.

The above strategy applies iteratively within the inner loop 197 to increase Nₐ toward the target 0.1Nₛ, and it reduces the number of inner loops down to five per iteration for practicality.

After enough MC samples are accepted at the step 180, the process 150 may proceed to the step 185 of the outer loop 196 to determine if enough iterations have been completed. As explained hereinabove, the quantity of iterations may be provided by a user as user input.

If enough iterations have not been completed, the process 150 may proceed to the step 190 of the outer loop 196, which includes selecting a plurality of simulation candidates from the plurality of accepted Monte Carlo samples (that were not rejected by the rejection sampling) for the next iteration. The quantity of simulation candidates may be provided by a user as user input. The step 190 includes selecting simulation samples for the next iteration, Sₙ, from the accepted MC samples, Su, and then going to the step 160 of the outer loop 196 in FIG. 1B. To best preserve the variety of parameters, the step 190 tries to pick the candidates that are “far away” from both S, and the historical simulation runs, Sₕ. Note that Sₕ stores all the completed simulation runs and it grows as the outer loop k proceeds

$${S}_{h}^{k + 1} = {S}_{h}^{k} ⋃ {S}_{n}^{k} . {S}_{n}$$

grows as the selection of simulation candidate proceeds and it is reset (Sₙ=Ø) at the beginning of each outer loop. Thus, the step 190 selects new simulation samples from the accepted MC samples and ensures diversity in the parameter space. Afterwards, the outer loop 196 may repeat iteratively to refine the results (e.g., HM results) until enough iterations have been completed at the step 185.

Simulation Candidate Selection—Indeed, once enough MC samples are collected (Nₐ=Nₜ), the step 190 selects N simulation samples out of the accepted MC samples Sₐ, and adds these designs to Sₙ for the next outer loop 196. The goal is to preserve the diversity of selections in each uncertainty parameter to reduce the similarity in the models (e.g., history-matched models) and best represent the uncertainty (e.g., the subsurface uncertainty). This is crucial to achieve reliable forecasts with numerical models. To prepare for this step, first, all the parameters may be mapped, including both continuous and categorical ones, to the normalized [0, 1] scale. Note that a categorical parameter may contain either numerical or nonnumerical values, and one needs to make sure that there is a clear ordering of the options. Then, as FIG. 3 illustrates, the step 190 scans all the accepted MC samples in Sₐ (dots that are marked as Accepted Samples) and calculates the sum of Euclidean distance (dashed arrows) of each sample with respect to all the existing simulation samples, including historical simulation samples and newly selected simulation candidates Sₕ∪Sₙ, in the normalized parameter space \hat{Ω}. For an arbitrary simulation candidate i (dot marked as Simulation Candidate) that is under investigation, the sum of Euclidean distance Dᵢ is expressed as follows:

$${D}_{i} = {\sum }_{j = 1}^{{N}_{h} + {N}_{n}} ‖ {\hat{x}}_{i} - {\hat{x}}_{j} ‖ , \qquad Equation ( 11 )$$

where \hat{x} is the parameter vector in \hat{Ω}, Nₕ is the size of Sₕ, and Nₙ is the size of the growing Sₙ as the selection proceeds. More specifically, i is an arbitrary simulation candidate under investigation, Dᵢ is sum of Euclidean distance, x is a parameter vector in \hat{Ω}, \hat{Ω} is a normalized parameter space, Nₕ is size of Sₕ, Sₕ is a set of historical simulation runs, Sₙ is a set of simulation samples for the next iteration, and Nₙ is size of the growing Sₙ as the selection proceeds. The procedure of simulation candidate selection is as follows: Calculate D for all accepted MC samples in Sₐ. Rank accepted MC samples in Sₐ with a descending D. Select the top accepted MC sample and move it from Sₐ to Sₙ. As Sₙ increases by one element, update D of the remaining accepted MC samples in Sₐ accordingly and repeat the selection process until N simulation candidates are collected.

Given the limited size of simulation samples, the simulation candidate selection process tries its best to preserve the diversity of each input parameter to improve the proxy reliability iteratively. The posterior distribution of each parameter can also be estimated from all the simulation samples.

At step 195, the process 150 includes filtering the plurality of simulation candidates from the plurality of iterations to select at least one numerical model for generating a prediction. A threshold may be utilized to filter the plurality of simulation candidates, such that at least one numerical model may be selected from the top case(s) of the simulation candidates after enough iterations have been performed in the step 185. A first threshold for a good case may be utilized for filtering, but it is beneficial to utilize a second threshold for a top case for filtering as the threshold for a top case may be more restrictive than the threshold for a good case. Threshold values may be provided by a user as user input. The thresholds are case-dependent. The threshold values may be determined via a trial and error process, and 5eₘ may be a good starting point for each objective function. In one embodiment, the target is to attain 1-5% of the entire simulation samples as the top cases for further usage.

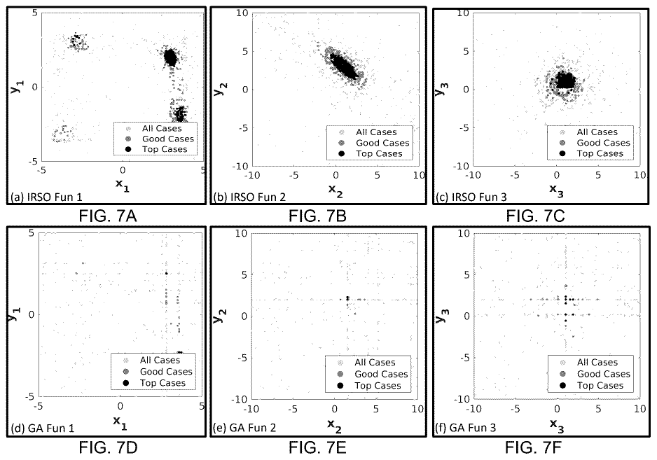

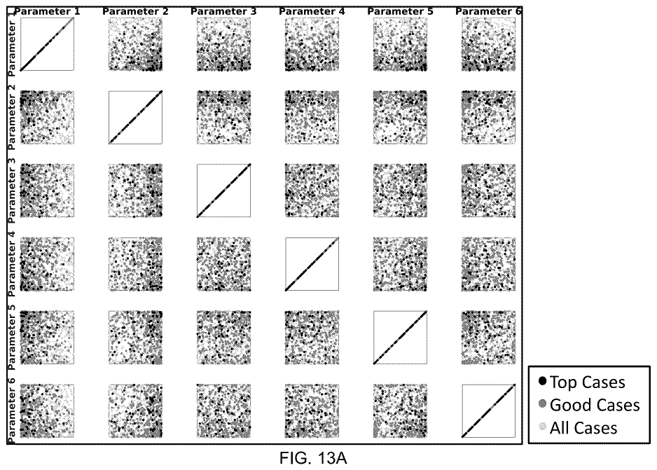

FIGS. 7A-7I and FIGS. 13A-13C herein relate to utilizing thresholds for good cases and top cases. In FIGS. 7A-7I, the thresholds are {ƒ₁(x), ƒ₂(x), ƒ₃(x)<20=20eₘ} for a good case and {ƒ₁(x), ƒ₂(x), ƒ₃(x)<5=5eₘ} for a top case. In 13A-13C, the thresholds are {BHP HM error<600 psi≈6.5eₘ, OPR HM error<600 B/D≈8eₘ} for a good case and {BHP HM error<600 psi≈6.5eₘ, OPR HM error<400 B/D≈5eₘ} for a top case.

The quantity of numerical models may be very small in comparison to the high quantities prior to this selection. In one embodiment, 1 numerical model may be selected from the top cases for generating a prediction. In one embodiment, 3 numerical models may be selected from the top cases for generating a prediction. In one embodiment, 5 numerical models may be selected from the top cases for generating a prediction. In one embodiment, 10 numerical models may be selected from the top cases for generating a prediction. The quantity of numerical models selected depends on the quantity of simulation candidates after the iterations have been completed, the desired prediction, etc.

At step 198, the process 150 includes generating the prediction utilizing the at least one numerical model that was selected. The prediction may be generated utilizing techniques known to those of ordinary skill in the art. A graphical display may present information relating to the generated prediction.

Regarding the prediction, in one embodiment, the prediction may include a net present value (NPV) prediction. In one embodiment, the prediction may include a hydrocarbon (e.g., oil) production prediction. In one embodiment, the prediction may include a field management related prediction (e.g., DPI, infill drilling opportunities, production plateau period, secondary/tertiary hydrocarbon recovery operations, etc.). The prediction may be related to a conventional subsurface formation. The prediction may be related to an unconventional subsurface formation, such as, but not limited to, a prediction may include a water cut prediction, an infill wellbore to maintain production rate related prediction, etc. In one embodiment, the prediction includes a net present value (NPV) prediction, a hydrocarbon production prediction, a field management related prediction, a water cut prediction, an infill wellbore to maintain production rate related prediction, or any combination thereof. Probabilistic analysis may optionally be performed to provide uncertainty for the prediction, such as probabilistic analysis to provide a hydrocarbon (e.g., oil) production prediction with a minimum and maximum range based on 10 numerical models. This is not an exhaustive list, and the prediction may be related to practically any aspect of reservoir management and the like that may benefit from predictions.

The prediction may be utilized for reservoir modeling, physical tasks, etc. in the oil and gas industry. For instance, sometimes the primary problem addressed is the accurate quantification of uncertainties in subsurface models for production forecasting in the oil and gas industry. The process 150 involves improving the precision and reliability of reservoir models by aligning them with historical production data. Integration of machine learning (ML) proxies with rejection sampling enhances multi-objective history matching (HM) in reservoir modeling. This approach may improve the accuracy and efficiency of subsurface assessments by reducing uncertainties in production forecasts. Besides reservoir modeling, the prediction may be utilized for fluid injection into a wellbore (e.g., waterflood, hydraulic fracturing, etc.), infill wellbore drilling, and other aspects in the oil and gas industry.

Various strengths of the process 150 have been highlighted herein. For instance, the classical Bayesian probabilistic HM techniques such as MCMC can depict the posterior distribution based on simulation samples. However, they require a large number of simulation runs by a sequential process to describe the posterior distributions, and thus it is computationally expensive and time-consuming. In the process 150, the iterative ML-based rejection sampling technique reduces the number of simulation runs.

Moreover, genetic algorithm (GA) and particle swarm optimization (PSO) were used as reference optimizers to compare with ML Proxies-Assisted IRSO (e.g., consistent with the process 150) because they are both widely used in multiobjective optimization and HM problems. The strengths of the ML Proxies-Assisted IRSO over the other two optimizers commonly used in the oil and gas industry, GA and PSO, are validated through three applications—an analytic six-parameter three-objective minimization problem (i.e., Analytic Case), a complex 120-parameter five-objective HM for Brugge field (i.e., Brugge Case), and a 41-parameter three-objective HM study for an offshore asset (i.e., Field Case). By comparing the performance against GA and PSO, this study demonstrates that the ML Proxies-Assisted IRSO was able to reduce the values of all the objectives rapidly and guarantees a better posterior distribution of simulation samples in the parameter space. Thus, the ML Proxies-Assisted IRSO would yield a series of reliable numerical models with a close match to the observation data and preserve a high diversity of model parameters. These numerical models can play an important role in modern reservoir management to facilitate the decision-making process. In addition, ML Proxies-Assisted IRSO itself only costs 0.2-0.5% of the computational resource and 1.4-12.0% of the waiting time in this particular study.

More information about the Analytic Case, Brugge Case, and Field Case is illustrated in Table 1. For instance, the Table 1 below lists the ML Proxies-Assisted IRSO parameters, where the number of iterations (Nᵢ) represents how many iterations that ML Proxies-Assisted IRSO repeats for the HM process, simulation sample size per iteration (N) is the number of simulation runs ML Proxies-Assisted IRSO submits every iteration, MC sample size (Nₛ) is the number of responses each proxy predicts during an MC sampling process, and the number of parameters corresponds to the number of variables to tune to match the observation data.

TABLE 1
ML Proxies-Assisted IRSO parameters.

| | Analytic | Brugge | Field |
|---|---|---|---|
| | Case | Case | Case |
| Number of iterations, Nᵢ | 20 | 20 | 20 |
| Simulation sample size per iteration, N | 50 | 50 | 50 |
| MC sample size, Nₛ | 10,000 | 10,000 | 10,000 |
| Number of uncertainty parameters | 6 | 120 | 41 |

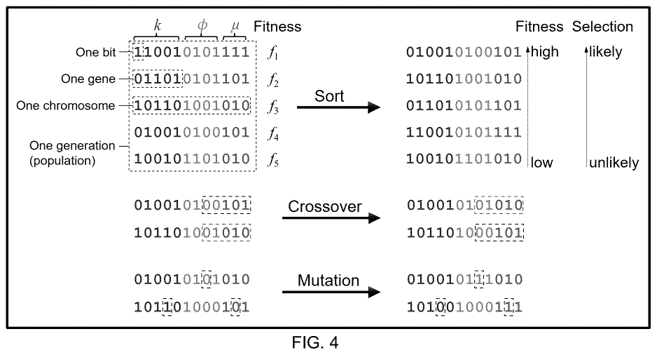

Genetic Algorithm (GA)—GA, initially introduced in 1975, is a robust evolutionary optimizer. Crossover, mutation, and selection are the three key evolutionary operations in GA. As the example in FIG. 4 illustrates (adapted from Wang, Z., He, J., Tanaka, S. et al. 2022. Efficient Drilling Sequence Optimization Using Heuristic Priority Functions. SPE J. 27 (1): 133-152. https://doi.org/10.2118/203986-PA, which is incorporated by reference), parameters such as k, u, and ø are interpreted as genes made up of a series of 0-1 bits, and all the genes form a chromosome (individual). For example, u utilizes a 3-bit gene (000, 001, . . . , 111) to represent up to 23 discrete values. The genes of k, μ, and φ concatenate an individual, and all individuals are called one generation (population). The initial generation is usually randomly created, and simulations are performed to attain the fitness (objective function) of each individual. Then, individuals are ranked according to their fitness values from high to low, and individuals with high fitness values are more probable to be selected for crossover and mutation. Crossover and mutation occur on the segment or bit level, and they both introduce randomness to the child individuals, and the population is ready for a new generation of operations. Table 2 lists the GA parameters used in the study. Note that the rank scaler controls the selection probability of the fittest chromosome: The probability decreases linearly from high to low fitness when the rank scaler equals 1.

TABLE 2
GA parameters.

| | Analytic | Brugge | Field |
|---|---|---|---|
| | Case | Case | Case |
| Number of generations | 20 | 20 | 20 |
| Population size | 50 | 50 | 50 |
| Mutation probability | 0.1 | 0.05 | 0.05 |
| Crossover probability | 0.9 | 0.9 | 0.9 |
| Rank scalar | 1.0 | 1.0 | 1.0 |

Due to its nature, GA does not follow the gradient information of the objective function, so it is unlikely to be trapped at local optima. It is efficient for optimization problems with a limited number of parameters; however, it converges slowly or even drops to a random selection process when there are hundreds of parameters.

Particle Swarm Optimization (PSO)—Similar to GA, PSO is also a population-based algorithm (e.g., Kennedy, J. and Eberhart, R. 1995. Particle Swarm Optimization. Paper presented at the ICNN'95-International Conference on Neural Networks, Perth, Australia, 27 November-1 December. https://doi.org/10.1109/ICNN.1995.488968, which is incorporated by reference). It mimics the interactions among organisms in a fish school or bird flock. Compared with concepts such as chromosome and population used in GA, individuals are called particles and the collection of particles is referred to as a swarm in PSO. This algorithm starts with all the particles located at different locations in the parameter domain. The location of each particle will change one iteration after another, according to its knowledge and the knowledge of its neighbors. The entire swarm will communicate and move until it reaches the stopping criteria. Mathematically, the position of particle i at iteration

$$k + 1 , {x}_{i}^{( k + 1 )} ,$$

can be updated via the position from the previous iteration plus the velocity at iteration

$$k + 1 , {v}_{i}^{( k + 1 )} :$$

$${x}_{i}^{( k + 1 )} = {x}_{i}^{( k )} + {v}_{i}^{( k + 1 )}$$

$${v}_{i}^{( k + 1 )} = ω {v}_{i}^{( k )} + {c}_{1} {r}_{1}^{( k )} ( {x}_{i , pbest}^{( k )} - {x}_{i}^{( k )} ) + {c}_{2} {r}_{2}^{( k )} ( {x}_{i , nbest}^{( k )} - {x}_{i}^{( k )} ) ,$$

where ω, c₁, and c₂ are the weights of inertial/cognitive/social terms, respectively;

$${r}_{1}^{( k )} and {r}_{2}^{( k )}$$

are the diagonal matrices with elements randomly distributed within the range [0,1], which may help avoid the solution being trapped in local optima;

$${x}_{i , pbest}^{( k )}$$

is the best location found by particle i itself in the history; and

$${x}_{i , nbest}^{( k )}$$

stores the best location found by particle i and its neighbors. In this study, the selected values of ω, c₁, and c₂ are shown in Table 3 following the suggestions from Clerc, M. 1999. The Swarm and the Queen: Towards a Deterministic and Adaptive Particle Swarm Optimization. Paper presented at the Congress on Evolutionary Computation-CEC99, Washington, DC, USA, 6-9 July. https://doi.org/10.1109/CEC.1999.785513, which is incorporated by reference. The neighbor size is set to be the same as the swarm size, meaning that each particle is fully connected to all the other particles in the swarm and

$${x}_{i , nbest}^{( k )}$$

represents the global best location indeed.

TABLE 3
PSO parameters.

| | Analytic Case | Brugge Case |
|---|---|---|
| Number of iterations | 20 | 20 |
| Swarm size | 50 | 50 |
| Neighbor topology | Fully connected | Fully connected |
| Neighbor size | 50 | 50 |
| Inertial weight | 0.729 | 0.729 |
| Cognitive/social weights | 1.494 | 1.494 |

Applications to Synthetic Cases—In this section, two synthetic multiobjective HM (minimization) problems are used to demonstrate the performance and advantages of the ML Proxies-Assisted IRSO over GA and PSO.

Minimization of a Six-Parameter Three-Objective Analytic Case—This case is created by combining three analytic functions that are often used for optimizer tests.
Fun 1—Himmelblau Function—The Himmelblau function is a multimodal function that can be used to test the capability of optimization algorithms. It has two independent parameters, and the expression is

$$f ( x , y ) = {( {x}^{2} + y - 11 )}^{2} + {( x + {y}^{2} - 7 )}^{2} \vert x , y \vert ⩽ 5. \qquad Equation ( 13 )$$

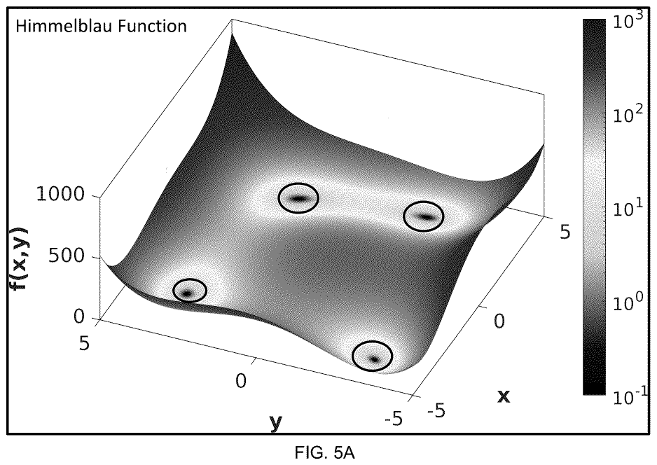

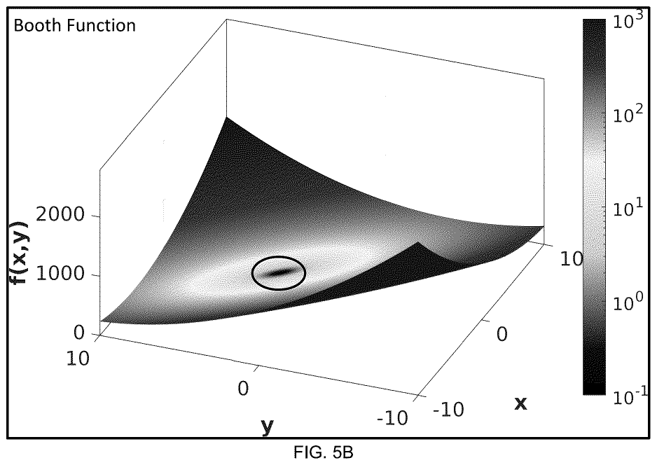

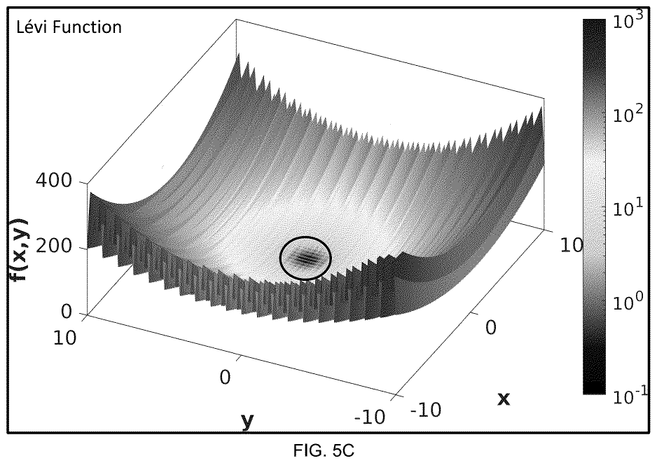

There are four local minima where ƒ(x, y)=0: (3.0, 2.0), (−2.81, 3.13), (−3.78, −3.28), (3.58, −1.85), as indicated by the dark regions with circles in FIG. 5A. The optimization algorithms may fail to locate all of the global minima and sometimes cannot detect all the dark regions with circles.
Fun 2—Booth Function—The Booth function is relatively simple compared with the other two functions. It has a smooth solution surface, two independent parameters, and the expression is

$$f ( x , y ) = {( x + 2 y - 7 )}^{2} + {( 2 x + y - 5 )}^{2} \vert x , y \vert ⩽ 10. \qquad Equation ( 14 )$$

There is one local minimum ƒ(1, 3)=0 illustrated by the dark region with a circle in FIG. 5B.
Fun 3—Lévi Function—The Lévi function has a lot of vibrations in the solution surface, and thus it could trap the searching paths of the gradient-based optimization algorithms. It has two independent parameters, and the expression is

$$f ( x , y ) = {sin}^{2} 3 π x + {( x - 1 )}^{2} ( 1 + {sin}^{2} 3 π y ) + {( y - 1 )}^{2} ( 1 + {sin}^{2} 2 π y ) \vert x , y \vert ⩽ 10. \qquad Equation ( 15 )$$

There is one local minimum illustrated by the dark region with a circle in FIG. 5C.

Apparently, it is easier to minimize the functions in three separate two-parameter one-objective optimizations rather than minimizing them simultaneously in a single optimization task. To test the capability of the ML Proxies-Assisted IRSO, the study intentionally combined Himmelblau [ƒ₁(x₁, y₁)], Booth [ƒ₂(x₂, y₂)], and Lévi [ƒ₃(x₃, y₃)] functions together to turn them into a six-parameter three-objective (labeled as Fun 1, Fun 2, and Fun 3, respectively) minimization problem:

$${min}_{x ∈ Ω} ( {f}_{1} ( x ) , {f}_{2} ( x ) , {f}_{3} ( x ) ) , \qquad Equation ( 16 )$$

where x=(x1, y1, x2, y2, x3, y3)^{T} and the parameter space Ω={x∥x₁, y₁|≤5 and |x₂, y₂, x₃, y₃|≤10}. Each objective function solely depends on two out of the six parameters, while the other four act as “dummy” parameters that have no impact on the objective function. For example, the Booth function [ƒ₂(x)] only depends on x₂ and y₂, and the other four parameters do not even exist in its expression. The measurement error is assumed as eₘ=1 and is identical for the three objective functions. The major challenge of this problem is that there are more irrelevant parameters than dependent variables for each objective function. Thus, it does great harm to optimization efficiency. This is an analogy to HM scenarios where each HM objective is only sensitive to a certain portion of the uncertainty parameters.

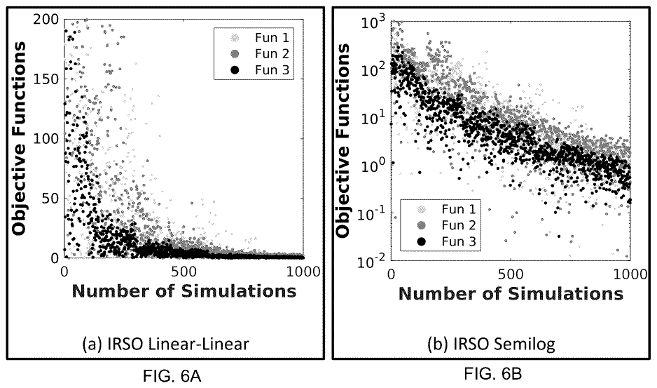

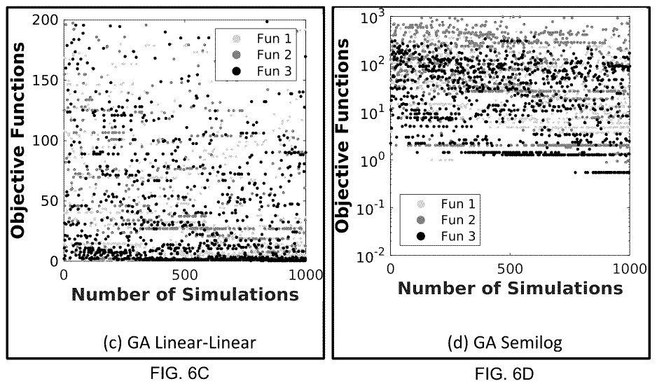

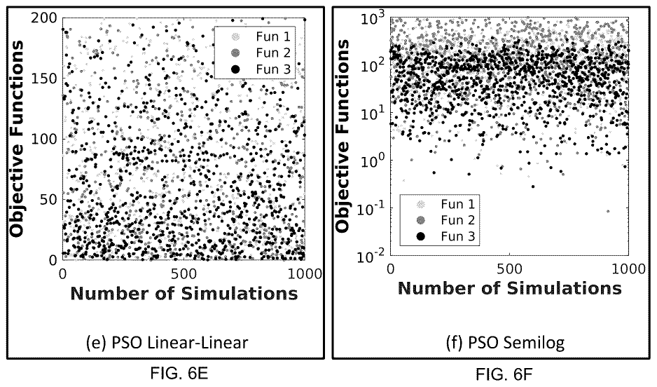

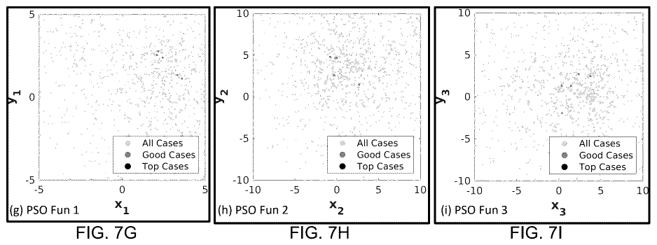

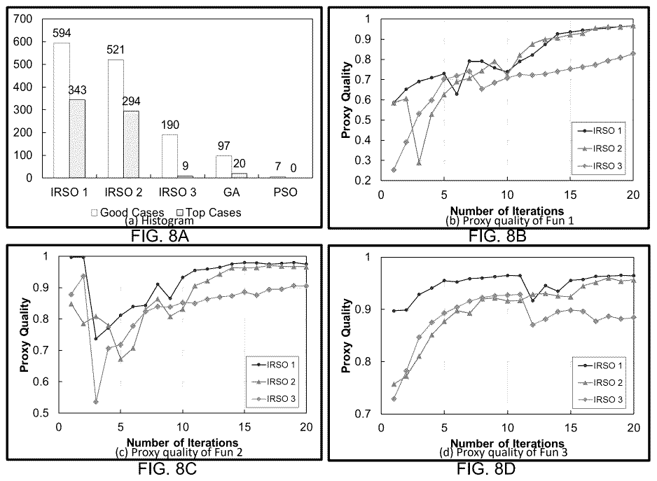

The proxies used in the ML Proxies-Assisted IRSO are listed in Scenario 1 in Table 4, and the HM results are displayed in FIGS. 6A-6F and FIGS. 7A-7I. FIGS. 6A-6F show the objective functions vs. the number of simulations in both linear-linear and semilog scales. One can observe that the ML Proxies-Assisted IRSO shows a good trend for objective function reduction, while the trend is not obvious for GA and PSO. A comparison of sampling results is illustrated in FIGS. 7A-7I, where one can directly see the sample distributions of each objective function. The dots represent all/good/top cases, where the threshold is {ƒ₁(x), ƒ₂(x), ƒ₃(x)<20=20eₘ} for a good case and {ƒ₁(x), ƒ₂(x), ƒ₃(x)<5=5eₘ} for a top case. It is obvious that the ML Proxies-Assisted IRSO successfully sampled near the global minima (dark regions with circles in FIGS. 5A-5C) of all three objective functions. Thus, the ML Proxies-Assisted IRSO attained the most good/top cases among all the methods. What is more, the diversity of the good/top samples is also much better than GA and PSO. For GA, the parameter diversity is confined by good/top cases found during early generations, and thus the children cases prefer to duplicate the selection. For Fun 2 and Fun 3, the performance looks fine; however, it prevents GA from exploring the remaining global minima for the multimodal Fun 1. Increasing the mutation and crossover probabilities could alleviate this issue, but it could also lead to an overexploration of the unnecessary solution space, resulting in a low optimization efficiency. Despite a relatively wider distribution of parameters and a good exploration of the parameter space, PSO failed to find any top cases and yielded the lowest number of good cases among the three methods, as listed in FIG. 8A.

TABLE 4
ML Proxies-Assisted IRSO proxy selections for the minimization
of a six-parameter three-objective analytic case.

| Scenario | Proxy Selections |
|---|---|
| 1 | Lasso, Ridge, Kriging, Splines, ANN, SVR, |
| | Random forest, Gradient boosting, AdaBoost, |
| | Quadratic polynomial without cross-terms, Quadratic |
| | polynomial with cross-terms |
| 2 | Random forest |
| 3 | Kriging |

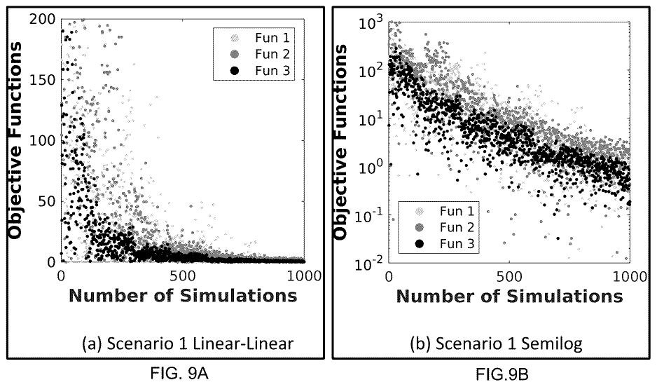

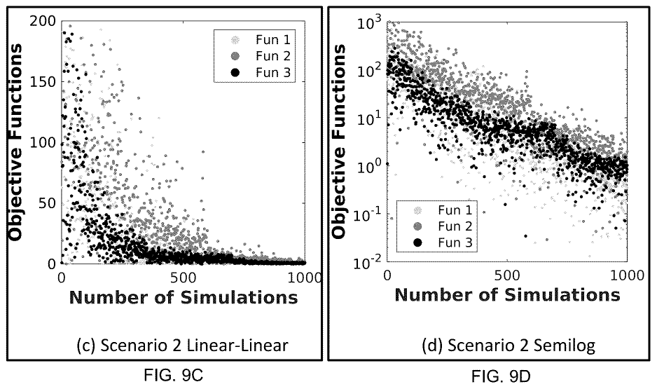

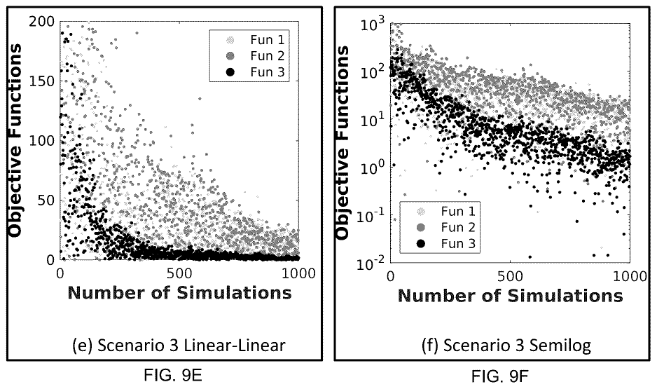

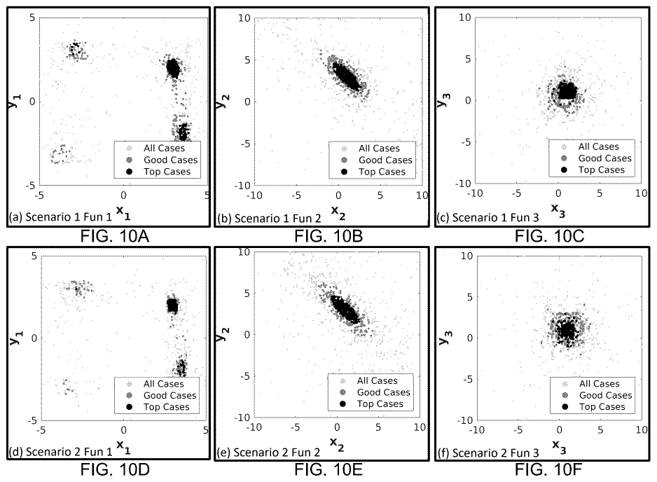

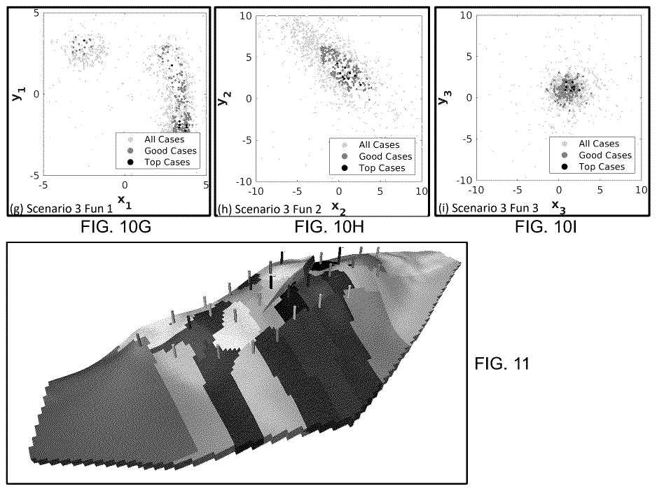

Note that FIG. 8A shows three scenarios of the ML Proxies-Assisted IRSO workflow, which are designed to better understand the benefit of the multiproxy feature. As summarized in Table 4, Scenario 2 only uses random forest, and Scenario 3 only has Kriging selected. The HM results are displayed in FIGS. 9A-9F and FIGS. 10A-10I. From FIGS. 9A-9F, one can conclude that Scenario 2 is slightly worse than Scenario 1, with a slower convergence in Fun 2, while Scenario 3 gives the slowest convergence in both Fun 1 and Fun 2. As a result, Scenario 3 yields the lowest amount of good/top cases among the three scenarios, and Scenario 2 shows a close performance with Scenario 1. FIGS. 8B through 8D shed light on the evolution of proxy quality with respect to the iteration of the three objective functions, and Scenario 1 outperforms Scenarios 2 and 3 in general, especially during the last several iterations. FIG. 8C presents V-shaped proxy quality curves, indicating an overfitting issue when the solution space is insufficiently explored during the first several iterations. The proxy quality defined in Eq. 8 may fail to depict the reliability of proxy prediction, especially during the first several iterations where the simulation sample size is small. Another important observation is that random forest used in this study does a better job than Kriging, as the proxy quality curves of Scenario 2 are higher than those of Scenario 3 in general. This study illustrates that different proxies have different application scopes, and it is better to select multiple types of proxies to guarantee a more robust and reliable optimization performance.

HM of a 120-Parameter Five-Objective Brugge Case—This subsection presents the study for the Brugge field, which is a Brent-type synthetic reservoir with medium oil designed to test the efficiency of optimization algorithms (Peters, E., Arts, R. J., Brouwer, G. K. et al. 2010. Results of the Brugge Benchmark Study for Flooding Optimization and History Matching. SPE Res Eval & Eng 13 (3): 391-405. https://doi.org/10.2118/119094-PA, which is incorporated by reference). The reservoir dimensions are approximately 32,808×9,843×200 ft³ with 139×48×9 gridblocks, where 43,036 are active cells. There are 20 producers (P01-P20) and 10 injectors (I01-I10) in the field, and one region was created for each of them as shown in FIG. 11. The following 120 uncertainty parameters are selected for this HM problem: a) Pore volume (PV) multipliers (1×30 regions); b) Permeability multipliers (1×30 regions); c) Vertical-to-horizontal permeability ratios (1×30 regions); d) Skin factors (1×30 wells).

The HM targets are the bottomhole pressure (BHP) of each well and the oil production rate (OPR) of each producer, which are further grouped into the following five objective functions, with three related to BHP and two related to OPR: a) BHP-INJ represents the BHP HM error of all the injectors (I01-I10). b) BHP-PRD-1 represents the BHP HM error of the first 10 producers (P01-P10). c) BHP-PRD-2 represents the BHP HM error of the last 10 producers (P11-P20). d) OPR-PRD-1 represents the OPR HM error of the first 10 producers (P01-P10). c) OPR-PRD-2 represents the OPR HM error of the last 10 producers (P11-P20). The measurement error is assumed to be 5% of the measurement value for the five objective functions.

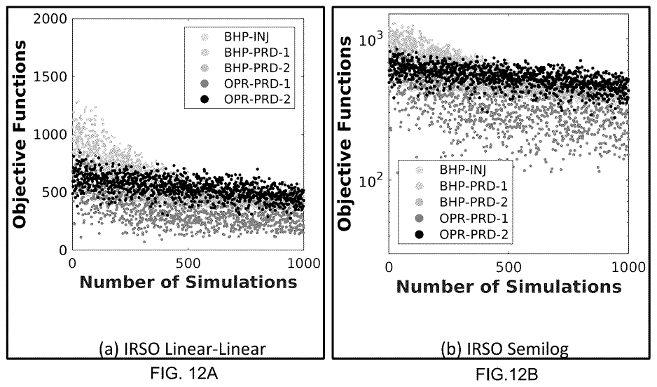

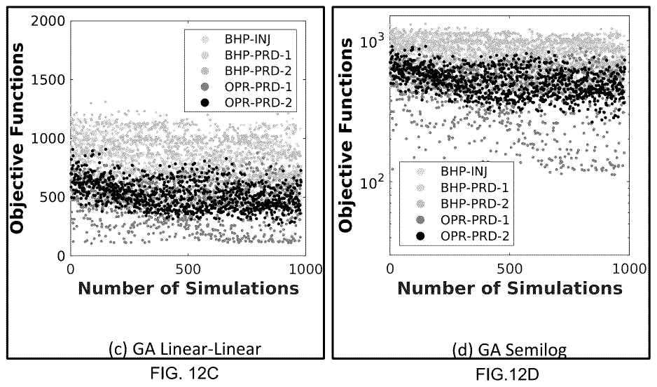

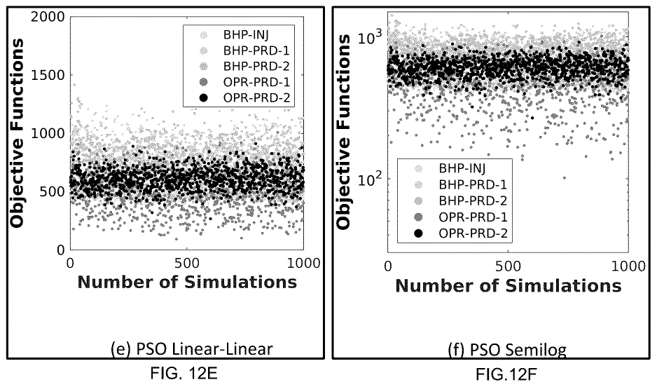

FIGS. 12A-12F show the objective function values vs. the number of simulations in both linear-linear and semi log scales. One can observe that ML Proxies-Assisted IRSO shows a clear trend for objective function reduction while the trend is not obvious for GA and PSO. The sampling results for the first six uncertainty parameters are illustrated in FIGS. 13A-13C. The dots represent all/good/top cases, where the thresholds are {BHP HM error<600 psi≈6.5eₘ, OPR HM error<600 B/D≈8eₘ} for a good case and {BHP HM error<600 psi≈6.5eₘ, OPR HM error<400 B/D≈5eₘ} for a top case. It is also clear in the parameter space that the distribution of top and good samples from ML Proxies-Assisted IRSO covers the target solution space of multiobjective function densely, while the samples from GA and PSO only give a limited coverage. That means ML Proxies-Assisted IRSO preserves a good variety of parameters in the history-matched models.

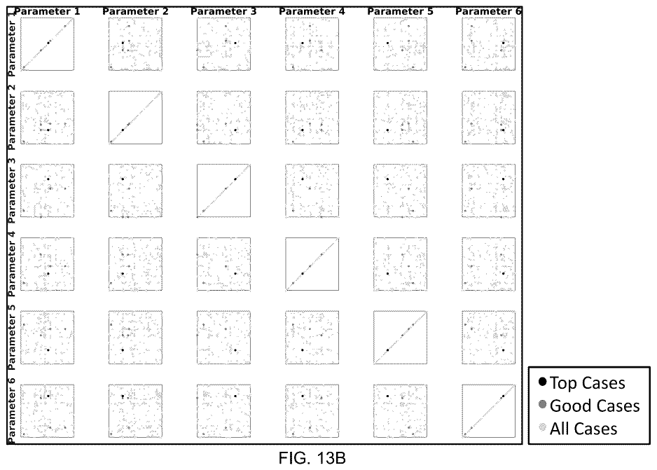

FIG. 14A shows the comparison of total sample counts of good and top cases among the three HM methods. As the figure illustrates, ML Proxies-Assisted IRSO successfully provides the largest number of good and top cases over GA and PSO. The proxy quality evolution with respect to iteration for all the five HM objectives is illustrated in FIG. 14B. One observes that the proxy quality of each objective improves as more simulation samples are collected.

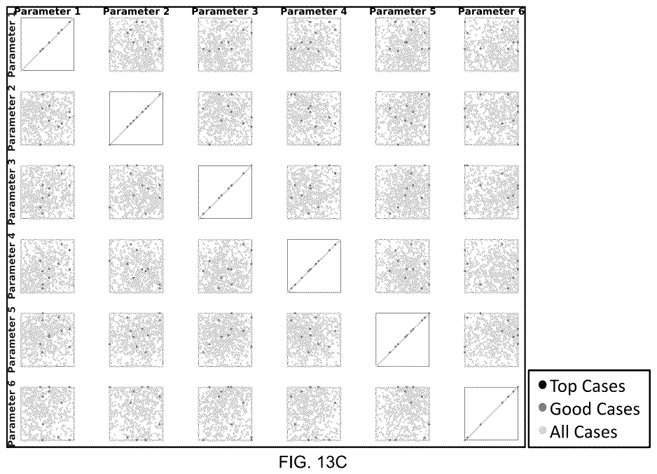

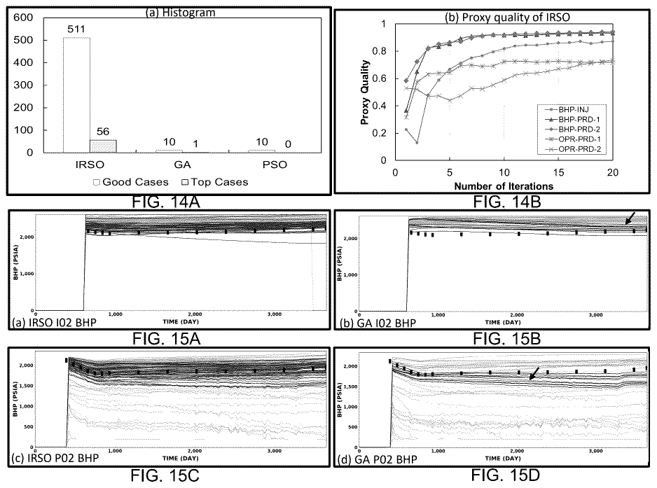

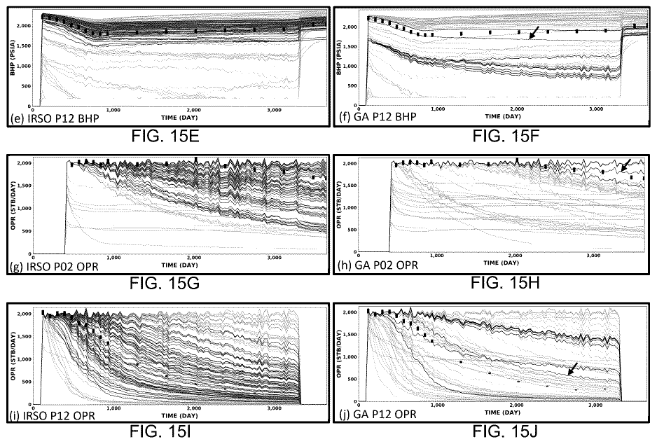

To better illustrate the well-level matches, FIGS. 15A-15J take the second well of each objective function as an example and illustrate a comparison of the first iteration/generation (gray curves), top cases (darker curves in FIGS. 15A, 15C, 15E, 15G, and 15I as well as the darker curves with arrows in FIGS. 15B, 15D, 15F, 15H, and 15J), good cases of GA (darker curves without arrows in FIGS. 15B, 15D, 15F, 15H, and 15J), and observation data (black boxes) between ML Proxies-Assisted IRSO and GA. GA yields only one top case, so good cases are also included to help depict the general performance of GA. One can observe that GA and ML Proxies-Assisted IRSO present similar outcomes for the first iteration/generation and ML Proxies-Assisted IRSO top cases and GA top and good cases show a spread around the observation data. Remember that the curves that are top cases have lower HM errors than the curves that are good cases, so one can conclude that ML Proxies-Assisted IRSO is better at capturing the diversity of model parameters even at lower HM errors. Depending on the different requirements for the well-level HM errors, one can further design and tune the local uncertainty parameters on the basis of the regional values suggested by the top and good cases, to improve the HM results of some specific wells.

Application to a Deepwater Reservoir—The ML Proxies-Assisted IRSO workflow was applied to the oil reservoir in the deepwater (referred to as “Field X” throughout the study).

Brief Overview of Field X—Field X consists of two Middle and Lower Miocene reservoirs with multistacked pay zones (21,000-24,000 ft TVDSS). The oil in Field X is trapped in a four-way closure formed by the development of a classic turtle structure with fault crossings across the field. The reservoir of interest has an average net-to-gross of 50%, a porosity of 20%, a permeability of 200 md, and a water saturation of 0.25. The wells were put on production at different times, resulting in 1-7 years of production history depending on the well. There are 41 uncertainty parameters including: a) Three nonnumerical categorical variables on the net sand model, porosity/permeability/saturation model, and compartmentalization model, respectively (each variable has three options of P10/P50/P90); b) Three nonnumerical categorical variables on the structural grid, fluid pressure/volume/temperature, and compact tables, respectively (each variable has three options of low/mid/high); c) Four relative permeability model parameters; d) Four oil-water contacts; e) One global transmissibility multiplier; f) Eight transmissibility multipliers between compartments; g) One vertical/horizontal permeability ratio; h) Seventeen aquifer PV multipliers. The first six parameters are nonnumerical categorical, and the rest are all numerical continuous ones that were further discretized into various options by the modelers when designing the HM problem. Thus, all the parameters are categorical in this field application.

The HM targets are the shut-in BHP (SBHP) and water cut (WCT) from five producers, and modular dynamic tester (MDT) pressure data from two producers, which are grouped into the following three objective functions: a) SBHP represents the SBHP HM error of five wells. b) WCT represents the WCT HM error of five wells. c) MDT represents the MDT data HM error of two wells. The measurement error eₘ is 100 psi for both SBHP and MDT and 0.05 for WCT.

Well historical controls are set to be liquid production cumulative together with a BHP constraint of each well. The HM target is to calibrate the reservoir model with historical production data to attain reliable and representative models with the subsurface uncertainty embedded successfully.

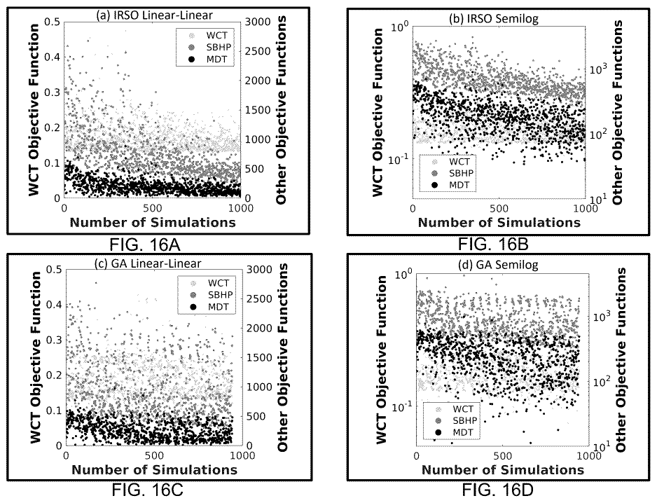

HM Results for Field X—Both ML Proxies-Assisted IRSO and GA are used for Field X HM while PSO is not selected due to its relatively poor performance in the synthetic case applications. FIGS. 16A-16D show the objective function values vs. the number of simulations in both linear-linear and semilog scales. One can observe that ML Proxies-Assisted IRSO shows a good trend for objective function reduction, while the trend is less obvious for GA. When judging whether a history-matched model is acceptable in the multiobjective HM, one must check and compare all the objective functions. For example, GA seems to yield several runs with a lower WCT or MDT error than ML Proxies-Assisted IRSO when comparing subplots (b) and (d); however, it turns out that at least one of the remaining objective functions has relatively high values after a careful check. Thus, those cases are unlikely to be selected as the top ones. The best practice is to always pick from the good and top cases for further analysis.

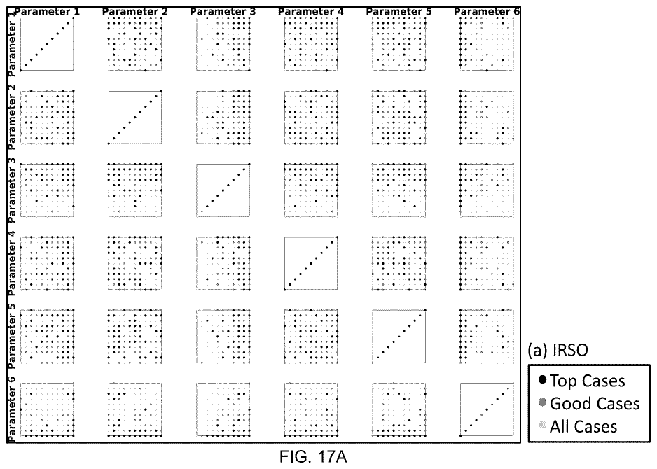

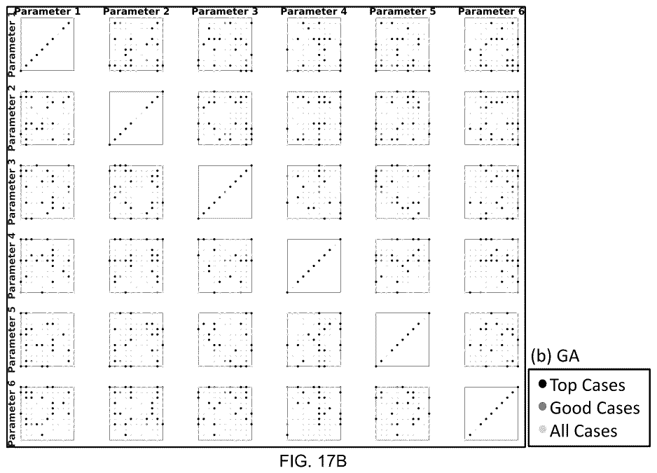

The sampling results are illustrated in FIGS. 17A-17B using six parameters that all have 11 values. The dots represent all/good/top cases, where the thresholds are {WCT HM error<0.14≈9.1eₘ, SBHP HM error<800 psi≈8eₘ, MDT HM error<800 psi≈8eₘ} for a good case and {WCT HM error<0.135≈8.7eₘ, SBHP HM error<650 psi≈6.5eₘ, MDT HM error<650 psi≈6.5eₘ} for a top case. One can directly see the sample distributions in the parameter space, where the distributions of ML Proxies-Assisted IRSO top and good cases can still represent the parameter space, while the top and good cases of GA give less coverage. Again, ML Proxies-Assisted IRSO preserves a good variety of parameters in the history-matched models. Compared with the Brugge case with a continuous parameter space, Field X has a discrete one due to the categorical variables. The discrete parameter space is beneficial to GA and less favorable to ML Proxies-Assisted IRSO because it greatly simplifies the number of parameter combinations from infinity to a finite number. That explains why GA attains a better performance than in the previous two applications.

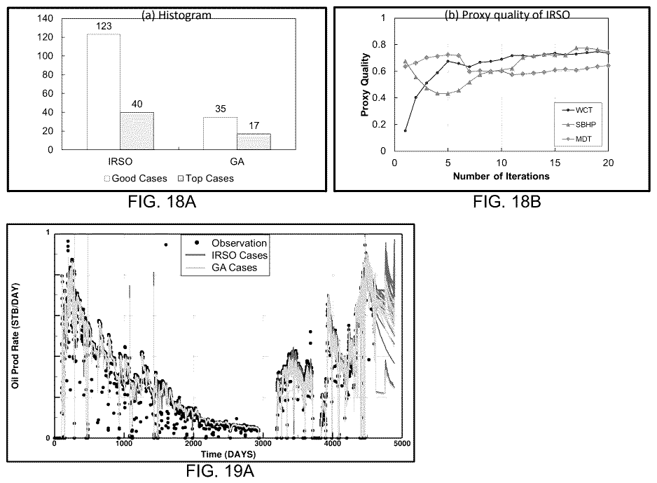

FIG. 18A presents the comparison between the two approaches. One can see that ML Proxies-Assisted IRSO successfully achieves more good and top cases over GA. Another observation is that WCT is the most difficult HM objective to improve for both approaches and the high variance of WCT measurements among the wells should be the main reason. The proxy quality evolution with respect to iteration for all three HM objectives is illustrated in FIG. 18B, where one observes the general trend of proxy quality improvement with more simulation samples added. Compared with synthetic cases, the field application is more challenging: None of the proxy quality curves go above 0.8 after 20 iterations, indicating the relation between input parameters and output HM objectives is hard to depict with the current proxy settings. The proxy quality mainly depends on the complexity of the problem, including the number of parameters, types of parameters, correlation between parameters and the objective functions (linearity level), and capability of the proxy. For the Brugge case, there are only four types of parameters (PV, permeability, vertical/horizontal permeability ratio, and skin factor) and the 120 parameters are all continuous. Thus, the correlation between the parameters and objective functions is relatively simple for the proxies used in ML Proxies-Assisted IRSO. The Field X application has many more types of parameters including geological models (net sand, porosity/permeability/saturation, compartmentalization, structural grid, etc.), fluid model (pressure/volume/temperature), rock model (compact tables), phase distribution (regional oil-water contacts), and aquifer (17 PV multipliers), which lead to a strong discrete and nonlinear solution space. Thus, proxies cannot perform as well as the Brugge case.

In addition, the problem setup is also important-how to parameterize the uncertainty, how to set the objective function, whether there are any unrealistic observation data, and so on. This, however, is not the primary discussion of this study because it often depends on the practitioners, especially in the field studies. Field X is particularly challenging because the problem was not originally prepared for the ML Proxies-Assisted IRSO workflow (e.g., categorical parameters were designed to limit the MC sampling resolution). However, ML Proxies-Assisted IRSO yields more than twice history-matched models over GA, which are further used for reliable production forecasting to best represent the subsurface uncertainty.

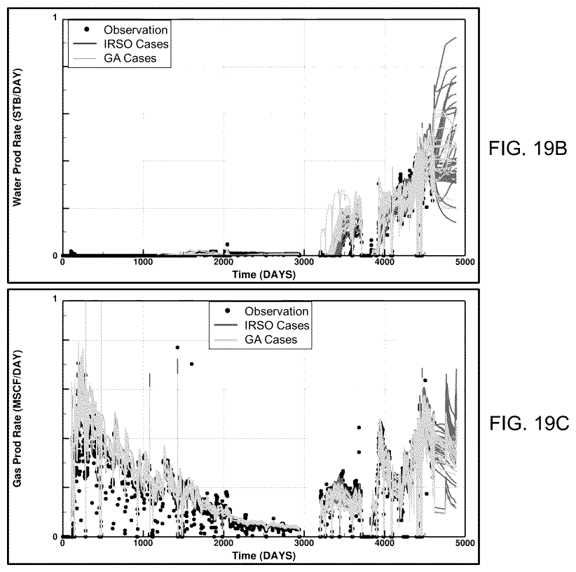

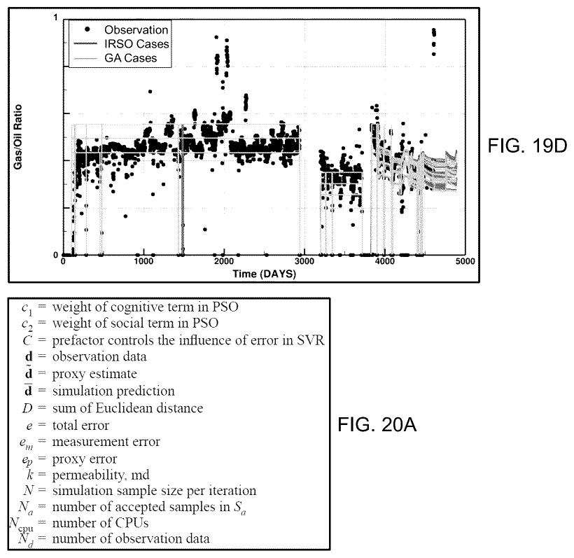

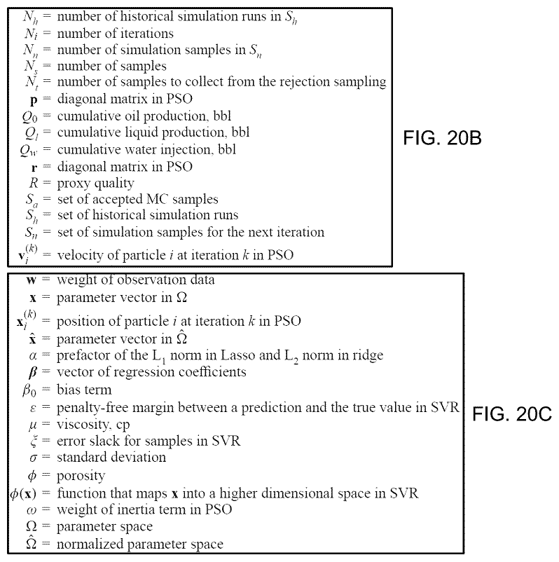

To better illustrate the top cases, FIGS. 19A-19D show the comparisons between GA (17 models) and ML Proxies-Assisted IRSO (40 models) via OPR, water production rate, gas production rate, and gas/oil ratio. The HM period is the first 4,600 days, followed by 1 year of production forecast with y-axes normalized to [0, 1] scale. Compared with GA, ML Proxies-Assisted IRSO top cases give wider forecasting ranges of the four properties. This demonstrates that ML Proxies-Assisted IRSO is better at preserving the diversity of model parameters and depicting the subsurface uncertainty than GA.

ML Proxies-Assisted IRSO Computational Cost Estimate—To better evaluate the computational cost, two new concepts were defined—total central processing unit (CPU) time and total clock time. Total CPU time refers to the sum of computational costs of all CPUs, and it is a measure of computational resources consumed during the process. Total clock time refers to the waiting time for users to get the results under a given computational resource with concurrent runs and parallel computing. As shown in Table 1, the number of simulation runs is N×Nᵢ=50×20=1,000. The total CPU and clock times of simulation and ML Proxies-Assisted IRSO are summarized in Tables 5 and 6, respectively.

The simulation was conducted using N_{cpu}=20 per job, with an average clock time of 28 minutes and an average CPU time of 28 N_{cpu}=560 minutes, where N_{cpu} represents the number of CPUs. Thus, the total CPU time is 560×1,000=560,000 minutes and the total clock time is 28×Nᵢ=560 minutes, assuming 50 concurrent jobs per iteration, and thus the clock time of each iteration is only 28 minutes. Similarly, the total CPU and clock times were evaluated with 1, 2, 4, 8, and 16 CPU(s). As Table 5 illustrates, the total CPU time increases as N_{cpu} increases, meaning a growing computational cost; the total clock time decreases as N_{cpu} increases, meaning a shorter waiting time for the results.

TABLE 5
Simulation CPU and clock times of Field X.

| CPU Number | 20 | 16 | 8 | 4 | 2 | 1 |
|---|---|---|---|---|---|---|
| Average clock time (minutes) | 28 | 31 | 47 | 79 | 143 | 271 |
| Total CPU time (minutes) | 560,000 | 499,284 | 377,719 | 316,937 | 286,545 | 271,350 |
| Total clock time (minutes) | 560 | 624 | 944 | 1,585 | 2,865 | 5,427 |

Table 6 displays the total CPU and clock times of proxy test and MC sampling processes and the cost of the rest of the components in ML Proxies-Assisted IRSO is trivial. In general, seven ML proxies are more expensive than Kriging and Spline, and quadratic polynomials with/without cross-terms are orders of magnitude cheaper. AdaBoost is the most expensive one in this study, so it is assumed that the rest of the proxies are as expensive as AdaBoost to simplify the estimate. The proxy test time increases as the simulation samples accumulate and the average is 0.28 minutes per iteration. The total CPU time is 0.28×(Nᵢ−1)×3 (objective functions)×11 (proxies)=174 minutes and the total CPU time is 0.28×(Nᵢ−1)=5 minutes. MC sampling takes 3.75 minutes per iteration at a fixed number of MC samples (Nₛ=10,000). The total CPU time is 3.75×(Nᵢ−1)×3 (objective functions)×5 (inner loops)=1,069 minutes and the total CPU time is estimated as 3.75×(Nᵢ−1)=71 minutes. Remember that MC sampling is only conducted for the best proxy of each objective function and it is repeated during each inner loop.

TABLE 6
ML Proxies-Assisted IRSO CPU and clock times of Field X.

| | | | ML Proxies- | ML Proxies- |
|---|---|---|---|---|
| | Proxy | MC | Assisted | Assisted |
| | Test | Sampling | IRSO | IRSO |
| | (minutes) | (minutes) | (minutes) | (%) |
| AdaBoost | 0.28 | 3.75 | — | — |
| Total CPU time | 174 | 1,069 | 1,243 | 0.2-0.5 |
| Total clock time | 5 | 71 | 76 | 1.4-12.0 |

Combining the costs, the total CPU and clock times of ML Proxies-Assisted IRSO are 1,243 minutes and 76 minutes, respectively. If 20 CPUs are used for parallel simulation, ML Proxies-Assisted IRSO accounts for 1,243/(1,243+560,000)=0.2% of the total CPU time and 77/(77+560)=12.0% of the total clock time of the entire HM process. These numbers change to 0.5% and 1.4% using one-CPU strategy instead. Notice that the total clock time of simulation is underestimated using the average clock time, while both total CPU and clock times of ML Proxies-Assisted IRSO are overestimated assuming all proxies are as expensive as AdaBoost, so the maximum ML Proxies-Assisted IRSO cost is 0.2-0.5% of the total CPU time and 1.4-12.0% of the total clock time, depending on N_{cpu}.

The main ML Proxies-Assisted IRSO workflow was built in C++ while the ML-based proxies were coded using Python. Thus, there is still room to speed up the ML Proxies-Assisted IRSO HM process (e.g., converting scripts from Python to C++), enabling parallel computation for proxy test and MC sampling, and stopping proxy testing when either proxy quality is good (beyond a certain threshold) or the best proxy selection is stable.

This study presented a DoE-based multiobjective HM workflow using ML Proxies-Assisted IRSO and illustrated its advantages over the commonly used optimizers such as GA and PSO. ML Proxies-Assisted IRSO takes full advantage of various proxies to efficiently explore the solution space with MC sampling. The proxies are improved iteratively and MC samples are rejected according to the total error of each HM objective function, and the new simulation designs for the next iteration are selected from the accepted MC samples to best preserve the subsurface uncertainty.

The ML Proxies-Assisted IRSO workflow was tested by multiobjective multiparameter examples such as an analytic minimization problem, a Brugge field waterflood, and a deepwater oil field. By comparing the performance against GA and PSO, the study demonstrated that ML Proxies-Assisted IRSO can both reduce the values of all the HM objectives rapidly and guarantee a better distribution of simulation samples in the parameter space. Thus, ML Proxies-Assisted IRSO would yield a series of reliable numerical models with a close match to the observation data and a high diversity of selections in each model parameter. These numerical models can play an important role in modern reservoir management to facilitate a reliable decision-making process.

The study identified two challenges throughout the applications of the ML Proxies-Assisted IRSO. First, proxy testing and MC sampling are time-consuming for the ML proxies in ML Proxies-Assisted IRSO. For the field application, the maximum ML Proxies-Assisted IRSO cost is 0.2-0.5% of the total CPU time and 1.4-12.0% of the total clock time, depending on the number of CPUs per simulation run. The tenfold cross-validation requires rebuilding the proxy 10 times during each test, and the cost grows along with the number of simulation samples; MC sampling is even more expensive than proxy test because the MC sample size is much larger than the simulation sample size in this study. They both prevent the study from conducting tens of thousands of simulation runs and using orders of magnitude more than 10,000 MC samples during these applications. Second, the hyperparameters of all the ML proxies are preset and kept fixed during the iterative HM process, regardless of the problem complexity and the types/numbers of uncertainty parameters and objective functions. Hyperparameter optimization is crucial for ML algorithms; however, this study focuses on developing the overall workflow, so it is out of the scope. Thus, the study avoided drawing conclusions on which ML algorithms are the best fit for general HM applications in the oil and gas industry. The general recommendation from the study is that the more types of proxies selected considering the computational resource available, the better. In future work, the plan is to continue improving the capability, efficiency, and integrity of the ML Proxies-Assisted IRSO workflow to address some of the aforementioned challenges. More information is available at Wang, Zhenzhen, Tanaka, Shusci, Zhang, Yanfen, and Xian-Huan Wen. “Multiobjective History Matching Using Machine Learning Proxies-Assisted Iterative Rejection Sampling.” SPE J. 29 (2024): 5002-5021. doi: https://doi.org/10.2118/219767-PA, which is incorporated by reference.

The present invention relates to a system that incorporates novel machine learning architectures for building a numerical model. These architectures, which surpass human mental processes, operate beyond predefined algorithms and adapt dynamically to input data. In particular, the system leverages deep learning models, neural networks, and other advanced techniques to achieve unprecedented performance.

While particular embodiments are described above, it will be understood it is not intended to limit the invention to these particular embodiments. On the contrary, the invention includes alternatives, modifications, and equivalents that are within the spirit and scope of the appended claims. Numerous specific details are set forth in order to provide a thorough understanding of the subject matter presented herein. But it will be apparent to one of ordinary skill in the art that the subject matter may be practiced without these specific details. In other instances, well-known methods, procedures, components, and circuits have not been described in detail so as not to unnecessarily obscure aspects of the embodiments.

The terminology used in the description of the invention herein is for the purpose of describing particular embodiments only and is not intended to be limiting of the invention. As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, operations, elements, and/or components, but do not preclude the presence or addition of one or more other features, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

As used herein, the use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of +10 percent of the given numeric value provided such a deviation does not alter the end function or result of the value. Therefore, a value of about 1% can be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

As used herein, “obtaining” data or information may include one or more of accessing, acquiring, analyzing, determining, examining, identifying, loading, locating, opening, receiving, retrieving, reviewing, selecting, storing, and/or otherwise obtaining the data or information.

As used herein, the term “objective” and “objective function” are used synonymously herein.

As used herein, a “well” or a “wellbore” refers to a single hole, usually cylindrical when viewed in at least piecewise increments, that is drilled into a reservoir. A well may be drilled in one or more directions. For example, a well may include a vertical well or section of the well, a horizontal well or section of the well, a deviated well or section of the well, and/or other type of well or section of the well. A well may be drilled in the reservoir for exploration and/or recovery of resources. A plurality of wells (e.g., tens to hundreds of wells) or a plurality of well are often used in a field depending on the desired outcome.

A well may be drilled into a reservoir using practically any drilling technique and equipment known in the art, such as geosteering, directional drilling, etc. Drilling the well may include using a tool, such as a drilling tool that includes a drill bit and a drill string. Drilling fluid, such as drilling mud, may be used while drilling in order to cool the drill tool and remove cuttings. Other tools may also be used while drilling or after drilling, such as measurement-while-drilling (MWD) tools, seismic-while-drilling tools, wireline tools, logging-while-drilling (LWD) tools, or other downhole tools. After drilling to a predetermined depth, the drill string and the drill bit may be removed, and then the casing, the tubing, and/or other equipment may be installed according to the design of the well. The equipment to be used in drilling the well may be dependent on the design of the well, the reservoir, the hydrocarbons and/or other subsurface resources being produced, and/or other factors.

A well may include a plurality of components, including but not limited to a casing, a liner, a tubing string, a sensor, a packer, a screen, a gravel pack, artificial lift equipment (e.g., an electric submersible pump (ESP)), and/or other components. If a well is drilled offshore, the well may include one or more of the previous components plus other offshore components, such as a riser. A well may also include equipment to control fluid flow into the well (e.g., injecting fluid for waterflooding, injecting fluid for hydraulic fracturing, etc.), control fluid flow out of the well, or any combination thereof. For example, a well may include a wellhead, a choke, a valve, and/or other control devices. These control devices may be located on the surface, in the subsurface (e.g., downhole in the well), or any combination thereof.

In some embodiments, the same control devices may be used to control fluid flow into and out of the well. In some embodiments, different control devices may be used to control fluid flow into and out of a well. In some embodiments, the rate of flow of fluids through the well may depend on the fluid handling capacities of the surface facility that is in fluidic communication with the well. The equipment to be used in controlling fluid flow into and out of a well may be dependent on the well, the subsurface region, the surface facility, and/or other factors. Moreover, sand control equipment and/or sand monitoring equipment may also be installed (e.g., downhole and/or on the surface). A well may also include any completion hardware that is not discussed separately. The term “well” may be used synonymously with the terms “borehole,” “wellbore,” or “well bore.” The term “well” is not limited to any description or configuration described herein.

As used herein, “hydraulic fracturing” is one way that hydrocarbons may be recovered (sometimes referred to as produced) from a reservoir in an economic manner. For example, hydraulic fracturing may entail preparing a fracturing fluid and injecting that fracturing fluid into the well at a sufficient rate and pressure to open existing fractures and/or create fractures in the reservoir. The fractures permit hydrocarbons to flow more freely into the well. In the hydraulic fracturing process, the fracturing fluid may be prepared on-site to include at least proppants. The proppants, such as sand or other particles, are meant to hold the fractures open so that hydrocarbons may more easily flow to the well. The fracturing fluid and the proppants may be blended together using at least one blender. The fracturing fluid may also include other components in addition to the proppants.

The well and the reservoir proximate to the well are in fluid communication (e.g., via perforations), and the fracturing fluid with the proppants is injected into the well through a wellhead of the well using at least one pump (oftentimes called a fracturing pump). The fracturing fluid with the proppants is injected at a sufficient rate and pressure to open existing fractures and/or create fractures in the reservoir. As fractures become sufficiently wide to allow proppants to flow into those fractures, proppants in the fracturing fluid are deposited in those fractures during the injection of the fracturing fluid. After the hydraulic fracturing process is completed, the fracturing fluid is removed by flowing or pumping it back out of the well so that the fracturing fluid does not block the flow of hydrocarbons to the well. The hydrocarbons may enter the same well from the reservoir and go up to the surface for further processing.

The equipment to be used in preparing and injecting the fracturing fluid may be dependent on the components of the fracturing fluid, the proppants, the well, the reservoir, etc. However, for simplicity, the term “fracturing apparatus” is meant to represent any tank(s), mixer(s), blender(s), pump(s), manifold(s), line(s), valve(s), fluid(s), fracturing fluid component(s), proppants, and other equipment and non-equipment items related to preparing the fracturing fluid and injecting the fracturing fluid.

As used herein, the term “hydrocarbon” refers to a compound containing carbon and hydrogen atoms. Hydrocarbons may include liquid hydrocarbons (also known as oil or petroleum), gas hydrocarbons, a combination of liquid hydrocarbons and gas hydrocarbons (e.g., including gas condensate), etc. For simplicity, many examples in this disclosure relate to the production of hydrocarbons. However, this disclosure applies to other produced fluid (e.g., produced water from a well, produced water from multiple wells, etc.), such as produced fluid in a liquid phase, produced fluid in a gas phase, or produced fluid in a combination of liquid phase and gas phase.

As used herein, a “reservoir” refers to a subsurface rock matrix in which a wellbore may be drilled. For example, a reservoir refers to a body of rock that is sufficiently distinctive and continuous such that it can be mapped. A reservoir stores resources, such as hydrocarbons, in its pore space. Reservoirs may vary in geologic features, such as, but not limited to, porosity, mineralogy, geomechanics, permeability, fluid saturation, presence of fractures, geologic structure (e.g., folds, manipulated by tectonic processes), thermal maturity, diagenetic alterations, etc. As used herein, in some embodiments, a reservoir may have a permeability of nanodarcy permeability to millidarcy permeability. The term reservoir may sometimes be used synonymously with the term “subsurface reservoir” or “subsurface formation” or “subsurface formation” or “subsurface volume of interest” or “subterranean formation” or “subsurface” or “formation” or the like. Indeed, the terms “hydrocarbon”, “reservoir”, and the like are not limited to any description or configuration described herein.

As used herein, an “unconventional reservoir” or “unconventional formation” generally requires intervention in order to recover hydrocarbons at economic flow rates or volumes. For example, an unconventional formation includes reservoirs having an unconventional microstructure in which fractures are used to recover hydrocarbons from the reservoir at sufficient flow rates or volumes (e.g., an unconventional reservoir generally needs to be fractured under pressure or have naturally occurring fractures in order to recover hydrocarbons from the reservoir at sufficient flow rates or volumes).

In some embodiments, the unconventional formation can include a reservoir having a permeability of less than 25 millidarcy (mD) (e.g., 20 mD or less, 15 mD or less, 10 mD or less, 5 mD or less, 1 mD or less, 0.5 mD or less, 0.1 mD or less, 0.05 mD or less, 0.01 mD or less, 0.005 mD or less, 0.001 mD or less, 0.0005 mD or less, 0.0001 mD or less, 0.00005 mD or less, 0.00001 mD or less, 0.000005 mD or less, 0.000001 mD or less, or less). In some embodiments, the unconventional formation can include a reservoir having a permeability of at least 0.000001 mD (e.g., at least 0.000005 mD, at least 0.00001 mD, 0.00005 mD, at least 0.0001 mD, 0.0005 mD, 0.001 mD, at least 0.005 mD, at least 0.01 mD, at least 0.05 mD, at least 0.1 mD, at least 0.5 mD, at least 1 mD, at least 5 mD, at least 10 mD, at least 15 mD, or at least 20 mD).

The unconventional formation can include a reservoir having a permeability ranging from any of the minimum values described above to any of the maximum values described above. For example, in some embodiments, the unconventional formation can include a reservoir having a permeability of from 0.000001 mD to 25 mD (e.g., from 0.001 mD to 25 mD, from 0.001 mD to 10 mD, from 0.01 mD to 10 mD, from 0.1 mD to 10 mD, from 0.001 mD to 5 mD, from 0.01 mD to 5 mD, or from 0.1 mD to 5 mD). The permeability of a particular formation can be determined by averaging measured permeability values from a series of representative core samples obtained from the formation. The formation may also be divided up into one or more hydrocarbon zones, and hydrocarbons can be produced from each desired hydrocarbon zone.

As used herein, a “conventional formation” may have a permeability higher than that of an “unconventional formation.” The permeability of a particular formation can be determined by averaging measured permeability values from a series of representative core samples obtained from the formation.

As used herein, it is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

Unless defined otherwise, all technical and scientific terms used herein have the same meanings as commonly understood by one of skill in the art to which the disclosed invention belongs. All citations referred herein are expressly incorporated by reference.

Although some of the various drawings illustrate a number of logical stages in a particular order, stages that are not order dependent may be reordered and other stages may be combined or broken out. While some reordering or other groupings are specifically mentioned, others will be obvious to those of ordinary skill in the art and so do not present an exhaustive list of alternatives. Moreover, it should be recognized that the stages could be implemented in hardware, firmware, software or any combination thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method of building a numerical model, the method comprising:
(a) defining a plurality of objective functions;
(b) defining a plurality of parameters and obtaining a plurality of values for the plurality of parameters;
(c) determining a plurality of simulation candidates from a plurality of iterations, for each iteration:
(i) running a simulation using the obtained plurality of parameters and the obtained plurality of values for the plurality of parameters to generate a plurality of simulation samples for the plurality of objective functions, wherein each simulation sample includes the corresponding parameter values, and wherein each simulation sample corresponds to at least one objective function with corresponding objective function values,
(ii) creating a plurality of proxies for each objective function and selecting a created proxy for each objective function, wherein at least one created proxy for each objective function includes a machine learning proxy,
(iii) performing Monte Carlo sampling using the selected proxies and the defined plurality of parameters to create a plurality of Monte Carlo samples, wherein each MC sample includes parameter values and objective function values,
(iv) rejecting a subset of the created plurality of Monte Carlo samples responsive to the plurality of objective functions and acceptance criteria, wherein the rejection sampling results in a plurality of accepted Monte Carlo samples, and
(v) selecting a plurality of simulation candidates from the plurality of accepted Monte Carlo samples for the next iteration; and
(d) filtering the plurality of simulation candidates from the plurality of iterations to select at least one numerical model for generating a prediction.

2. The method of claim 1, wherein the plurality of proxies comprises artificial neural network, ridge regression, lasso regression, support vector regression, random forest, adaptive boosting, gradient boosting, Kriging, Splines, linear, linear with cross terms, quadratic polynomial, full quadratic, or any combination thereof.

3. The method of claim 1, wherein selecting a created proxy for each objective function comprises utilizing an equation, wherein the equation comprises:
$$R = \frac{{σ}_{\hat{d} , \tilde{d}}}{{σ}_{\hat{d}} \cdot {σ}_{\tilde{d}}}$$
where \hat{d} is objective function estimated from simulation samples, \tilde{d} is proxy estimate with \hat{d} as blind data. σ_{\hat{d}} and σ_{\tilde{d}} are their corresponding standard deviations, and σ_{\hat{d},\tilde{d}} is covariance between them.

4. The method of claim 1, wherein at least one subiteration is utilized for (iii) performing Monte Carlo sampling and (iv) rejecting a subset of the created plurality of Monte Carlo samples.

5. The method of claim 1, wherein rejecting a subset of the created plurality of Monte Carlo samples responsive to the plurality of objective functions and acceptance criteria comprises utilizing an equation, wherein the equation comprises e₁=eₘ+eₚ where e is total error, and wherein
$${e}_{m} = \sqrt{\frac{{\sum }_{j = 1}^{{N}_{d}} {w}_{i} {e}_{m , i}^{2}}{{\sum }_{i = 1}^{{N}_{d}} {w}_{i}}}$$
where eₘ is measurement error, w is weight of observation data, and N_{d} is number of observation data, and wherein
$${e}_{p} = \sqrt{\frac{1}{{N}_{h}} {\sum }_{i = 1}^{{N}_{h}} \vert {\hat{d}}_{i} - {\tilde{d}}_{i} \vert}$$
where eₚ is proxy error, \hat{d} is objective function estimated from simulation results, \tilde{d} is proxy estimate with \hat{d} as blind data. Nₕ is size of Sₕ, and Sₕ is a set of historical simulation runs.

6. The method of claim 1, wherein selecting a plurality of simulation candidates from the plurality of accepted Monte Carlo samples for the next iteration comprises utilizing Euclidean distance.

7. The method of claim 6, wherein selecting a plurality of simulation candidates from the plurality of accepted Monte Carlo samples for the next iteration comprises utilizing an equation, wherein the equation comprises:
$${D}_{i} = {\sum }_{j = 1}^{{N}_{h} + {N}_{n}} ‖ {\hat{x}}_{i} - {\hat{x}}_{j} ‖$$
wherein i is an arbitrary simulation candidate under investigation, Dᵢ is sum of Euclidean distance, \hat{x} is a parameter vector in \hat{Ω}, \hat{Ω} is a normalized parameter space, Nₕ is size of Sₕ, Sₕ is a set of historical simulation runs, Sₙ is a set of simulation samples for the next iteration, and Nₙ is size of the growing Sₙ as the selection proceeds.

8. The method of claim 1, wherein filtering the plurality of simulation candidates from the plurality of iterations to select at least one numerical model for generating a prediction comprises utilizing a threshold to filter the plurality of simulation candidates.

9. The method of claim 1, further comprising generating the prediction utilizing the at least one numerical model that was selected.

10. The method of claim 9, wherein the prediction comprises a net present value prediction, a hydrocarbon production prediction, a field management related prediction, a water cut prediction, an infill wellbore to maintain production rate related prediction, or any combination thereof.

11. A computer system, comprising:
one or more processors;
memory; and
one or more programs, wherein the one or more programs are stored in the memory and configured to be executed by the one or more processors, the one or more programs including instructions that when executed by the one or more processors cause the computer system to build a numerical model, the method comprising:
(a) defining a plurality of objective functions;
(b) defining a plurality of parameters and obtaining a plurality of values for the plurality of parameters;
(c) determining a plurality of simulation candidates from a plurality of iterations, for each iteration:
(i) running a simulation using the obtained plurality of parameters and the obtained plurality of values for the plurality of parameters to generate a plurality of simulation samples for the plurality of objective functions, wherein each simulation sample includes the corresponding parameter values, and wherein each simulation sample corresponds to at least one objective function with corresponding objective function values,
(ii) creating a plurality of proxies for each objective function and selecting a created proxy for each objective function, wherein at least one created proxy for each objective function includes a machine learning proxy,
(iii) performing Monte Carlo sampling using the selected proxies and the defined plurality of parameters to create a plurality of Monte Carlo samples, wherein each MC sample includes parameter values and objective function values,
(iv) rejecting a subset of the created plurality of Monte Carlo samples responsive to the plurality of objective functions and acceptance criteria, wherein the rejection sampling results in a plurality of accepted Monte Carlo samples, and
(v) selecting a plurality of simulation candidates from the plurality of accepted Monte Carlo samples for the next iteration; and
(d) filtering the plurality of simulation candidates from the plurality of iterations to select at least one numerical model for generating a prediction.

12. The computer system of claim 11, wherein the plurality of proxies comprises artificial neural network, ridge regression, lasso regression, support vector regression, random forest, adaptive boosting, gradient boosting, Kriging, Splines, linear, linear with cross terms, quadratic polynomial, full quadratic, or any combination thereof.

13. The computer system of claim 11, wherein selecting a created proxy for each objective function comprises utilizing an equation, wherein the equation comprises:
$$R = \frac{{σ}_{\hat{d} , \tilde{d}}}{{σ}_{\hat{d}} \cdot {σ}_{\tilde{d}}}$$
where \hat{d} is objective function estimated from simulation samples, \tilde{d} is proxy estimate with \hat{d} as blind data. σ_{\hat{d}} and σ_{\tilde{d}} are their corresponding standard deviations, and σ_{\hat{d},\tilde{d}} is covariance between them.

14. The computer system of claim 11, wherein at least one subiteration is utilized for (iii) performing Monte Carlo sampling and (iv) rejecting a subset of the created plurality of Monte Carlo samples.

15. The computer system of claim 11, wherein rejecting a subset of the created plurality of Monte Carlo samples responsive to the plurality of objective functions and acceptance criteria comprises utilizing an equation, wherein the equation comprises e₁=eₘ+eₚ where e is total error, and wherein
$${e}_{m} = \sqrt{\frac{{\sum }_{j = 1}^{{N}_{d}} {w}_{i} {e}_{m , i}^{2}}{{\sum }_{i = 1}^{{N}_{d}} {w}_{i}}}$$
where eₘ is measurement error, w is weight of observation data, and N_{d} is number of observation data, and wherein
$${e}_{p} = \sqrt{\frac{1}{{N}_{h}} {\sum }_{i = 1}^{{N}_{h}} \vert {\hat{d}}_{i} - {\tilde{d}}_{i} \vert}$$
where eₚ is proxy error, \hat{d} is objective function estimated from simulation results, \tilde{d} is proxy estimate with \hat{d} as blind data. Nₕ is size of Sₕ, and Sₕ is a set of historical simulation runs.

16. The computer system of claim 11, wherein selecting a plurality of simulation candidates from the plurality of accepted Monte Carlo samples for the next iteration comprises utilizing Euclidean distance.

17. The computer system of claim 16, wherein selecting a plurality of simulation candidates from the plurality of accepted Monte Carlo samples for the next iteration comprises utilizing an equation, wherein the equation comprises:
$${D}_{i} = {\sum }_{j = 1}^{{N}_{h} + {N}_{n}} ‖ {\hat{x}}_{i} - {\hat{x}}_{j} ‖$$
wherein i is an arbitrary simulation candidate under investigation, Dᵢ is sum of Euclidean distance, \hat{x} is a parameter vector in \hat{Ω}, \hat{Ω} is a normalized parameter space, Nₕ is size of Sₕ, Sₕ is a set of historical simulation runs, Sₙ is a set of simulation samples for the next iteration, and Nₙ is size of the growing Sₙ as the selection proceeds.

18. The computer system of claim 11, wherein filtering the plurality of simulation candidates from the plurality of iterations to select at least one numerical model for generating a prediction comprises utilizing a threshold to filter the plurality of simulation candidates.

19. The computer system of claim 11, wherein the method further comprises generating the prediction utilizing the at least one numerical model that was selected.

20. The computer system of claim 19, wherein the prediction comprises a net present value prediction, a hydrocarbon production prediction, a field management related prediction, a water cut prediction, an infill wellbore to maintain production rate related prediction, or any combination thereof.
